(19) United States
(12) Patent Application Publication
(10) Pub. No.: US 2024/0321740 A1
(43) Pub. Date: Sep. 26, 2024

(54) THREE-DIMENSIONAL MEMORY DEVICE WITH BACKSIDE WORD LINE CONTACT VIA STRUCTURES AND METHODS OF FORMING THE SAME

(71) Applicant: SANDISK TECHNOLOGIES LLC, ADDISON, TX (US)

(72) Inventors: Takashi INOMATA, Yokkaichi (JP); Li LI, Yokkaichi (JP); Masanori OISUGI, Yokkaichi (JP)

(21) Appl. No.: 18/359,697

(22) Filed: Jul. 26, 2023

Related U.S. Application Data
(60) Provisional application No. 63/491,581, filed on Mar. 22, 2023.

(51) Int. Cl. H01L 23/528; H01L 23/522; H10B 41/10; H10B 41/27; H10B 41/40; H10B 43/10; H10B 43/27; H10B 43/40

(52) U.S. Cl. CPC H01L 23/5283; H01L 23/5226; H10B 41/10; H10B 41/27; H10B 41/40; H10B 43/10; H10B 43/27; H10B 43/40

(57) ABSTRACT

A semiconductor structure includes an alternating stack of insulating layers and electrically conductive layers, where the electrically conductive layers have different lateral extents that decrease along an upward vertical direction from a bottommost insulating layer to a topmost insulating layer of the insulating layers, a memory opening vertically extending through the alternating stack, a memory opening fill structure located in the memory opening and including a vertical stack of memory elements and a vertical semiconductor channel, and a layer contact via structure vertically extending through a subset of the electrically conductive layers and a subset of the insulating layers that includes the bottommost insulating layer, contacting a top surface of a topmost electrically conductive layer within the subset of the electrically conductive layers, and having a topmost surface below a horizontal plane including a topmost surface of the alternating stack.

### FIELD

The present disclosure relates generally to the field of semiconductor devices, and particularly to a three-dimensional semiconductor device including backside word line contact via structures and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure is provided, which comprises: an alternating stack of insulating layers and electrically conductive layers, wherein the electrically conductive layers have different lateral extents that decrease along an upward vertical direction from a bottommost insulating layer to a topmost insulating layer of the insulating layers; a memory opening vertically extending through the alternating stack; a memory opening fill structure located in the memory opening and comprising a vertical stack of memory elements and a vertical semiconductor channel; and a layer contact via structure vertically extending through a subset of the electrically conductive layers and a subset of the insulating layers that includes the bottommost insulating layer, contacting a top surface of a topmost electrically conductive layer within the subset of the electrically conductive layers, and having a topmost surface below a horizontal plane including a topmost surface of the alternating stack.

According to another aspect of the present disclosure, a method of forming a semiconductor structure is provided. The method comprises: forming an alternating stack of insulating layers and sacrificial material layers over a carrier substrate; forming an in-process assembly including a dielectric spacer and a sacrificial pillar structure through the alternating stack; forming a memory opening through the alternating stack; forming a memory opening fill structure in the memory opening, wherein the memory opening fill structure comprises a vertical stack of memory elements and a vertical semiconductor channel; forming stepped surfaces by patterning the alternating stack, wherein the alternating stack has lateral extents that decrease stepwise as a function of a vertical distance from the carrier substrate, and the in-process assembly is recessed during patterning of the alternating stack; forming a sacrificial plate structure over a top surface of the in-process assembly; replacing the sacrificial material layers with electrically conductive layers; removing the carrier substrate; and forming a layer contact via structure by replacing the sacrificial pillar structure and the sacrificial plate structure with portions of at least one conductive material, wherein the layer contact via structure contacts a segment of a top surface of an electrically conductive layer of the electrically conductive layers.

### BRIEF DESCRIPTION OF THE DRAWINGS

FIG. 1 is a schematic vertical cross-sectional view of an exemplary structure after formation of a stopper insulating layer, source-level material layers, and an alternating stack of insulating layers and sacrificial material layers over a carrier substrate according to an embodiment of the present disclosure.

FIG. 2A is a schematic vertical cross-sectional view of the exemplary structure after patterning memory openings, support openings, and contact via openings according to an embodiment of the present disclosure.

FIG. 2B is a top-down view of the exemplary structure of FIG. 2A. The vertical plane A-A′ is the cut plane of the vertical cross-sectional view of FIG. 2A.

FIG. 3 is a schematic vertical cross-sectional view of the exemplary structure after formation of an insulating liner layer according to an embodiment of the present disclosure.

FIG. 4A is a schematic vertical cross-sectional view of the exemplary structure after formation of a self-aligned etch mask layer according to an embodiment of the present disclosure.

FIG. 4B is a top-down view of the exemplary structure of FIG. 4A. The vertical plane A-A′ is the cut plane of the vertical cross-sectional view of FIG. 4A.

FIG. 5 is a schematic vertical cross-sectional view of the exemplary structure after vertically extending the contact via openings according to an embodiment of the present disclosure.

FIG. 6 is a vertical cross-sectional view of the exemplary structure after patterning the etch mask layer according to an embodiment of the present disclosure.

FIG. 7 is a vertical cross-sectional view of the exemplary structure after deposition of a dielectric fill material layer according to an embodiment of the present disclosure.

FIG. 8 is a vertical cross-sectional view of the exemplary structure after deposition of a sacrificial fill material layer according to an embodiment of the present disclosure.

FIG. 9 is a vertical cross-sectional view of the exemplary structure after formation of sacrificial pillar structures according to an embodiment of the present disclosure.

FIG. 10 is a vertical cross-sectional view of the exemplary structure after formation of an insulating cap layer according to an embodiment of the present disclosure.

FIG. 11 is a vertical cross-sectional view of the exemplary structure after formation of dielectric support pillar structures and in-process assemblies of a dielectric spacer, a sacrificial pillar structure, and an insulating cap according to an embodiment of the present disclosure.

FIG. 12 is a vertical cross-sectional view of the exemplary structure after removal of the etch mask layer according to an embodiment of the present disclosure.

FIGS. 13A-13D are sequential vertical cross-sectional views of a memory opening during formation of a memory opening fill structure according to an embodiment of the present disclosure.

FIG. 14A is a vertical cross-sectional view of the exemplary structure after formation of memory opening fill structures according to an embodiment of the present disclosure.

FIG. 14B is a top-down view of the exemplary structure of FIG. 14A. The vertical plane A-A′ is the cut plane of the vertical cross-sectional view of FIG. 14A.

FIG. 15A is a vertical cross-sectional view of the exemplary structure after formation of stepped surfaces by patterning the alternating stack according to an embodiment of the present disclosure.

FIG. 15B is a top-down view of the exemplary structure of FIG. 15A. The vertical plane A-A′ is the cut plane of the vertical cross-sectional view of FIG. 15A.

FIG. 16 is a vertical cross-sectional view of the exemplary structure after formation of a sacrificial etch stop liner layer and a sacrificial plate material layer according to an embodiment of the present disclosure.

FIG. 17A is a vertical cross-sectional view of the exemplary structure after formation of sacrificial plate structures including a respective vertical stack of a sacrificial etch stop liner and a sacrificial material plate portion according to an embodiment of the present disclosure.

FIG. 17B is a top-down view of the exemplary structure of FIG. 17A. The vertical plane A-A′ is the cut plane of the vertical cross-sectional view of FIG. 17A.

FIG. 18 is a vertical cross-sectional view of the exemplary structure after formation of a stepped dielectric material portion and a contact-level dielectric layer according to an embodiment of the present disclosure.

FIG. 19A is a vertical cross-sectional view of the exemplary structure after formation of isolation trenches according to an embodiment of the present disclosure.

FIG. 19B is a top-down view of the exemplary structure of FIG. 19A. The vertical plane A-A′ is the cut plane of the vertical cross-sectional view of FIG. 19A.

FIG. 20 is a vertical cross-sectional view of the exemplary structure after formation of a source-level cavity according to an embodiment of the present disclosure.

FIG. 21 is a vertical cross-sectional view of the exemplary structure after formation of a source contact layer according to an embodiment of the present disclosure.

FIG. 22 is a vertical cross-sectional view of the exemplary structure after formation of lateral recesses according to an embodiment of the present disclosure.

FIG. 23 is a vertical cross-sectional view of the exemplary structure after formation of electrically conductive layers according to an embodiment of the present disclosure.

FIG. 24A is a vertical cross-sectional view of the exemplary structure after formation of lateral isolation trench fill structures and drain contact via structures according to an embodiment of the present disclosure.

FIG. 24B is a top-down view of the exemplary structure of FIG. 24A. The vertical plane A-A′ is the cut plane of the vertical cross-sectional view of FIG. 24A.

FIG. 25 is a vertical cross-sectional view of the exemplary structure after formation of a memory die and attachment of a logic die to the memory die according to an embodiment of the present disclosure.

FIG. 26 is a vertical cross-sectional view of the exemplary structure after removal of the carrier substrate according to an embodiment of the present disclosure.

FIG. 27 is a vertical cross-sectional view of the exemplary structure after formation of a backside dielectric layer and contact pad cavities according to an embodiment of the present disclosure.

FIG. 28 is a vertical cross-sectional view of the exemplary structure after removal of the sacrificial pillar structures according to an embodiment of the present disclosure.

FIG. 29 is a vertical cross-sectional view of the exemplary structure after removal of the sacrificial etch stop liners according to an embodiment of the present disclosure.

FIG. 30 is a vertical cross-sectional view of the exemplary structure after removal of the sacrificial material plate portions according to an embodiment of the present disclosure.

FIG. 31 is a vertical cross-sectional view of the exemplary structure after vertically extending a source-contact backside opening according to an embodiment of the present disclosure.

FIG. 32 is a vertical cross-sectional view of the exemplary structure after formation of layer contact via structures and a source contact via structure according to an embodiment of the present disclosure.

### DETAILED DESCRIPTION

As discussed above, the embodiments of the present disclosure are directed to a three-dimensional semiconductor device including backside word line contact via structures and methods for manufacturing the same, the various aspects of which are described below. Embodiments of the disclosure can be employed to form various structures including a multilevel memory structure, non-limiting examples of which include three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

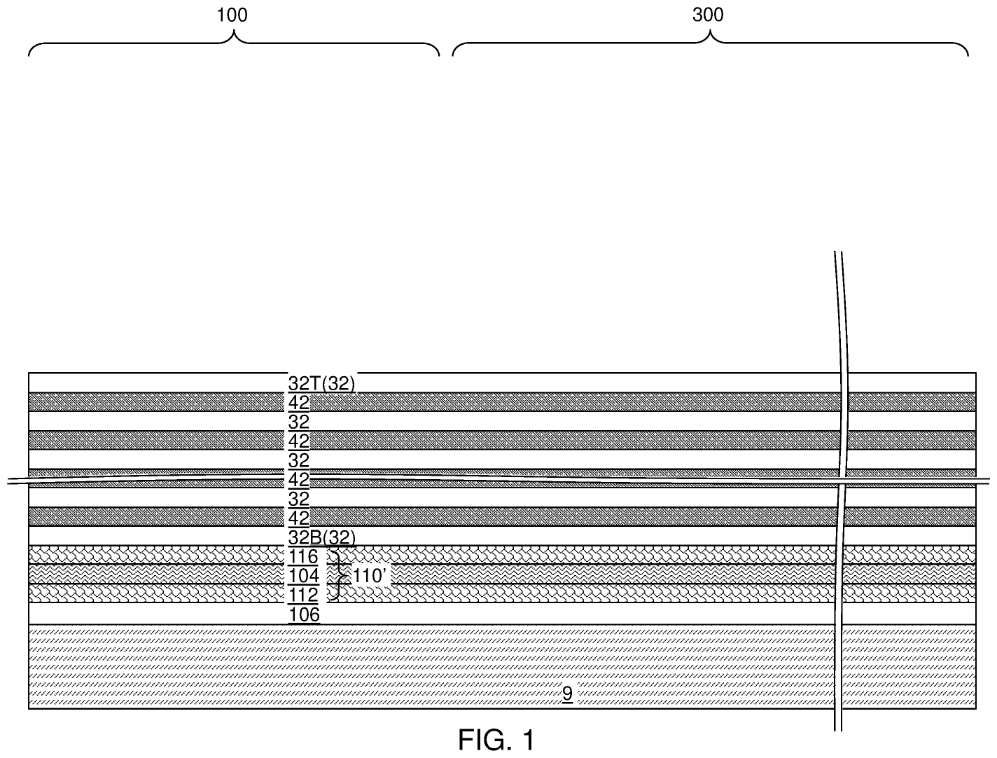

Referring to FIG. 1, an exemplary structure according to an embodiment of the present disclosure is illustrated. The exemplary structure comprises a carrier substrate 9, which may be a semiconductor substrate, an insulating substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process, such as a chemical mechanical polishing process is employed to subsequently remove the carrier substrate 9, the stopper material layer 106 may be subsequently employed as a polishing stopper material layer. If an etch process such as a wet etch process is employed to subsequently remove the carrier substrate 9, the stopper material layer 106 may be subsequently employed as an etch stop material layer. In one embodiment, the stopper insulating layer 106 comprises a dielectric material such as undoped silicate glass (i.e., silicon oxide), a doped silicate glass, or silicon nitride. The thickness of the stopper insulating layer 106 may be in a range from 50 nm to 600 nm, such as from 100 nm to 300 nm, although lesser and greater thicknesses may also be employed.

In-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material, such as undoped amorphous silicon, polysilicon, or silicon-germanium. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layer 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layer 110′. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers may be formed as, or may be subsequently replaced at least partly with, electrically conductive layers.

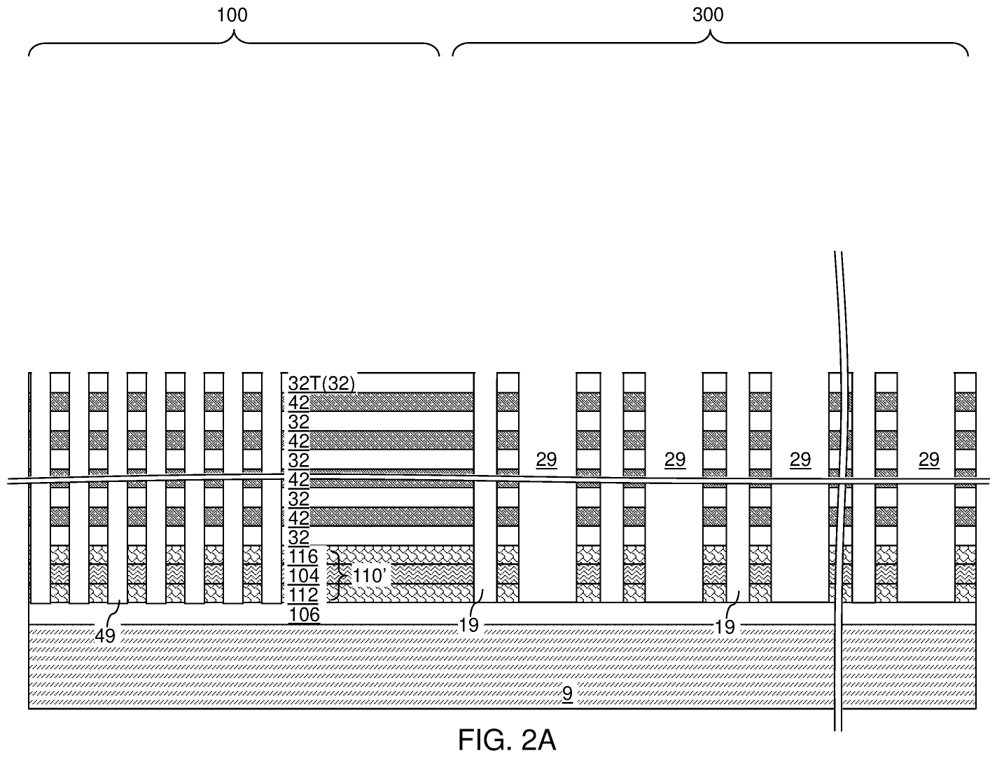

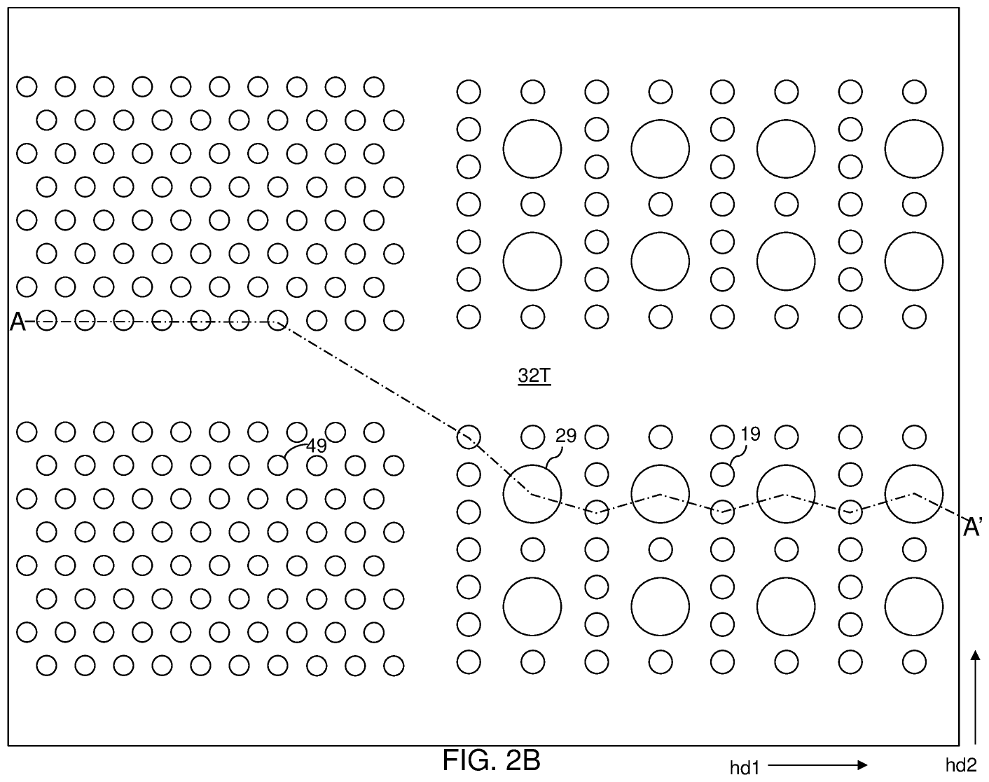

Referring to FIGS. 2A and 2B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100, contact via openings 29 that are formed in the contact region 300 in areas in which layer contact via structures (e.g. word line contact via structures) contacting a respective word line are to be subsequently formed, and support openings 19 that are formed in the contact region 300 around the contact via openings 29. Each of the memory openings 49, the contact via openings 29, and the support openings 19 can vertically extend through the alternating stack (32, 42) and partly into the in-process source-level material layers 110′ In one embodiment, bottom surfaces of the memory openings 49, the contact via openings 29, and the support openings 19 may be formed within the lower source-level semiconductor layer 112 or at an interface between the lower source-level semiconductor layer and the stopper insulating layer 106.

According to an aspect of the present disclosure, the contact via openings 29 may have a lateral dimension (such as a diameter) that is greater than the lateral dimension of the support openings 19, and is greater than the lateral dimension of the memory openings 49. For example, the contact via openings 29 may have a diameter in a range from 200 nm to 1,500 nm, such as from 300 nm to 1,000 nm, although lesser and greater thicknesses may be employed. The support openings 19 may have a diameter in a range from 60 nm too 400 nm, such as from 120 nm to 300 nm, although lesser and greater thicknesses may be employed. The memory openings 49 may have a diameter in a range from 60 nm too 400 nm, such as from 120 nm to 300 nm, although lesser and greater thicknesses may be employed. The ratio of the lateral dimension of the contact via openings 29 to the lateral dimension of the support openings 19 may be in a range from 1.5 to 10, such as from 2 to 5, although lesser and greater ratios may also be employed. The ratio of the lateral dimension of the contact via openings 29 to the lateral dimension of the memory openings 49 may be in a range from 1.5 to 10, such as from 2 to 5, although lesser and greater ratios may also be employed.

In one embodiment, the memory array region 100 may be laterally spaced apart from the contact region 300 along a first horizontal direction (e.g., word line direction) hd1. The memory openings 49 may comprise rows of memory openings 49 that are arranged along the first horizontal direction hd1 and laterally spaced apart along a second horizontal direction (e.g., bit line direction) hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2. Rows of contact via openings 29 may be formed in the contact region 300. Each row of contact via openings 29 may include a set of contact via openings 29 that are arranged along the first horizontal direction hd1.

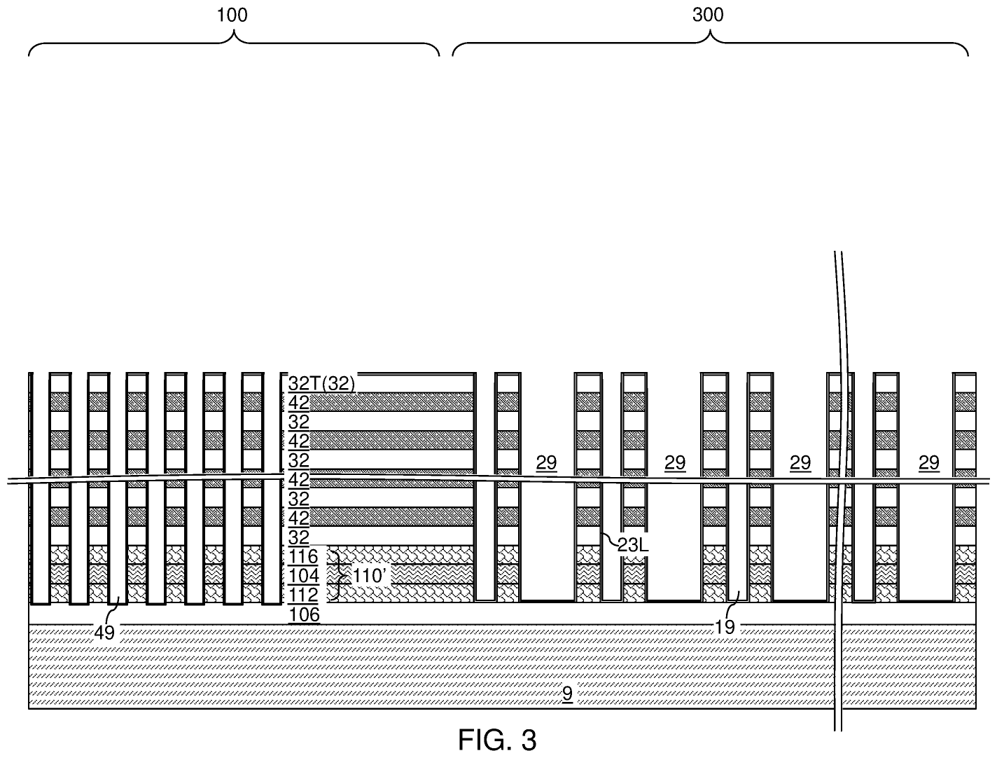

Referring to FIG. 3, an insulating liner layer 23L may be conformally deposited on the physically exposed surfaces of the memory openings 49, the support openings 19, and the contact via openings 29 and over the alternating stack (32, 42). The insulating liner layer 23L comprises a dielectric material, such as silicon oxide or a dielectric metal oxide. The thickness of the insulating liner layer 23L may be in a range from 10 nm to 30 nm, although lesser and greater thicknesses may also be employed.

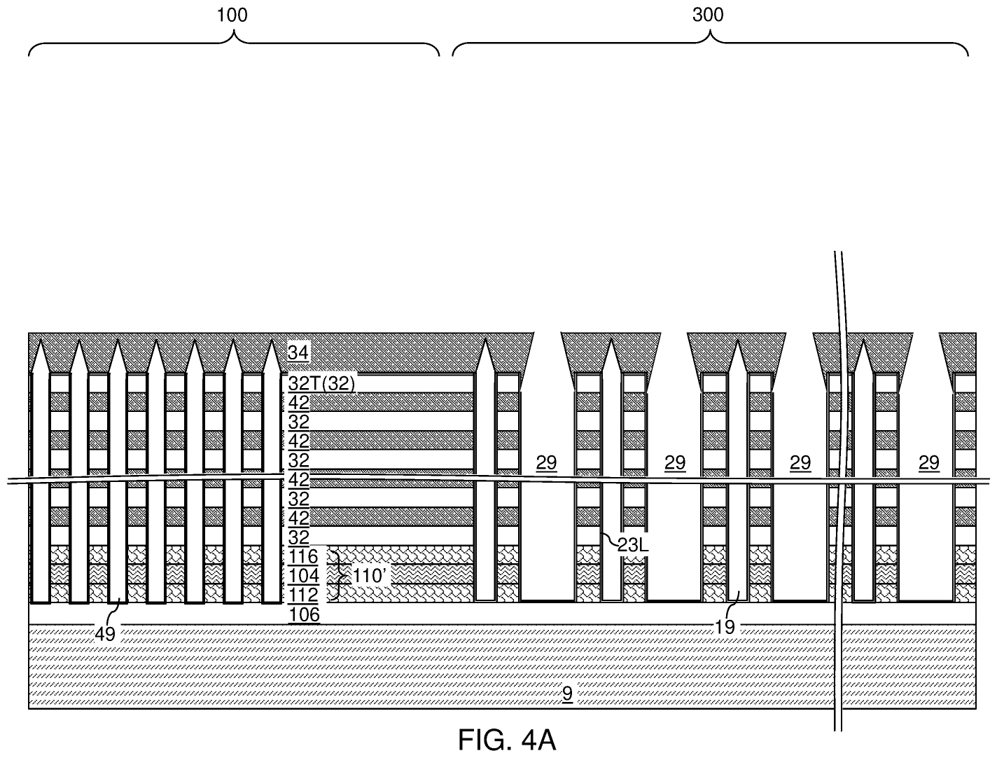

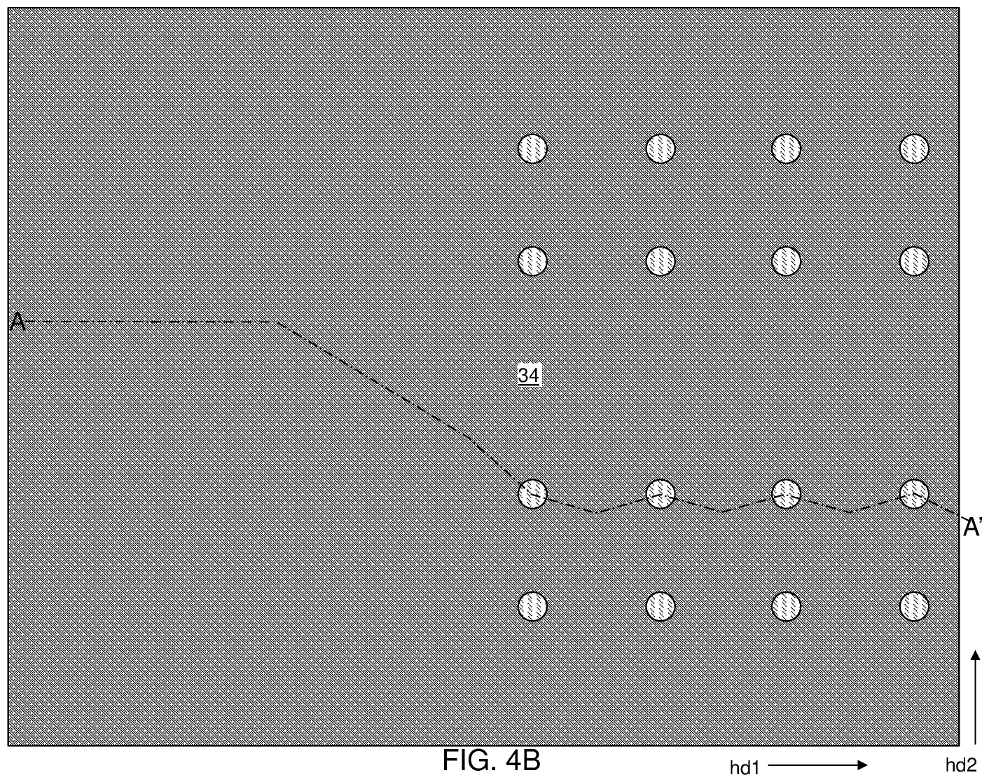

Referring to FIGS. 4A and 4B, an etch mask material can be anisotropically deposited to form an etch mask layer 34. For example, physical vapor deposition (e.g., sputtering) can be employed to deposit the etch mask material over the topmost surface of the alternating stack (32, 42) primarily along the downward vertical direction with a limited angular spread, which may be less than 30 degrees. In one embodiment, the etch mask material may comprise a dielectric material, such as silicon nitride, or may comprise a semiconductor material, such as polysilicon or amorphous silicon. The deposited etch mask material forms an etch mask layer 34, which can be a self-aligned etch mask layer that grows from the topmost surface of the alternating stack (32, 42) with a gradual spread in the lateral direction as the deposition process for the etch mask material progresses in time.

Due to the anisotropic nature and the finite spread of the deposited material during the anisotropic deposition process, the anisotropically deposited etch mask material accumulates around a top periphery of each opening (49, 19, 29) through the alternating stack (32, 42) such that openings in the etch mask layer gradually decrease in size as the deposition process for the etch mask material progresses. According to an aspect of the present disclosure, the duration of the etch mask deposition process can be selected such that openings in the etch mask layer 34 that overlie the narrower memory openings 49 and the support openings 19 are sealed prior to termination of the etch mask deposition process, while the openings in the etch mask layer 34 that overlie the wider contact via openings 29 are not sealed after the etch mask deposition process. Thus, openings are present in the etch mask layer 34 above the contact via openings 29 through the alternating stack (32, 42). The etch mask layer 34 may have a thickness in a range from 100 nm too 600 nm, such as from 200 nm to 400 nm, although lesser and greater thicknesses may be employed.

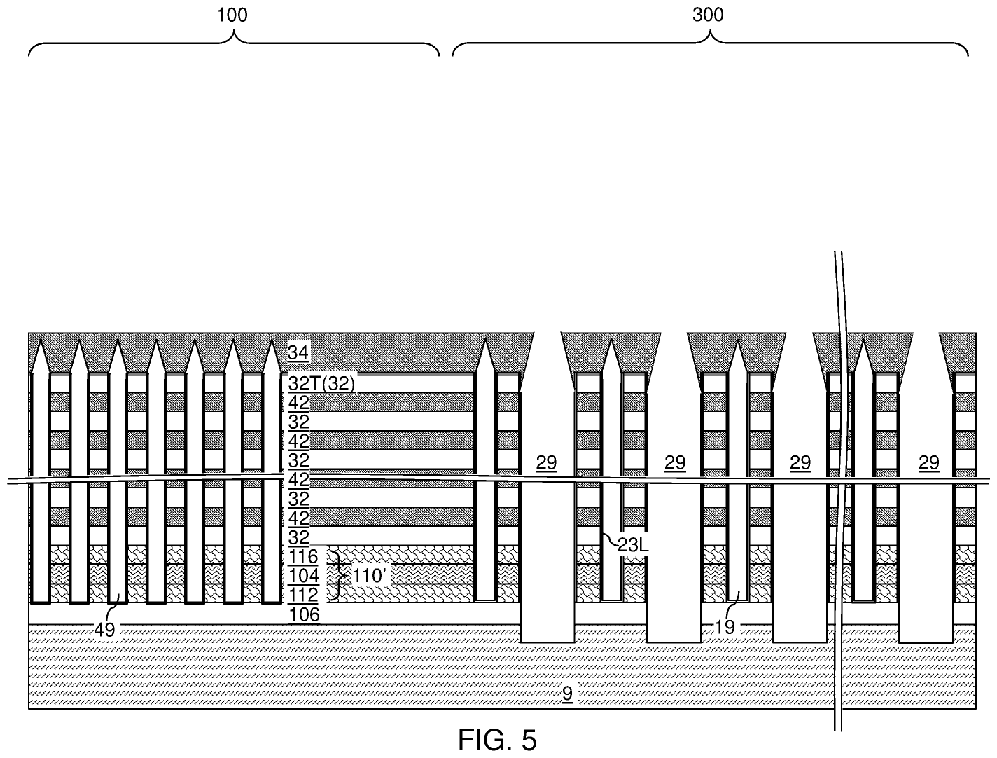

Referring to FIG. 5, an anisotropic etch process can be performed to vertically extend the contact via openings 29 through the stopper insulating layer 106 into an upper portion of the carrier substrate 9. Etchant ions enter through openings in the etch mask layer 34 into the contact via openings 29, and etch underlying material portions underneath each of the contact via openings 29 to vertically extend the contact via openings 29. A surface of the carrier substrate 9 can be physically exposed at the bottom of each of the contact via openings 29.

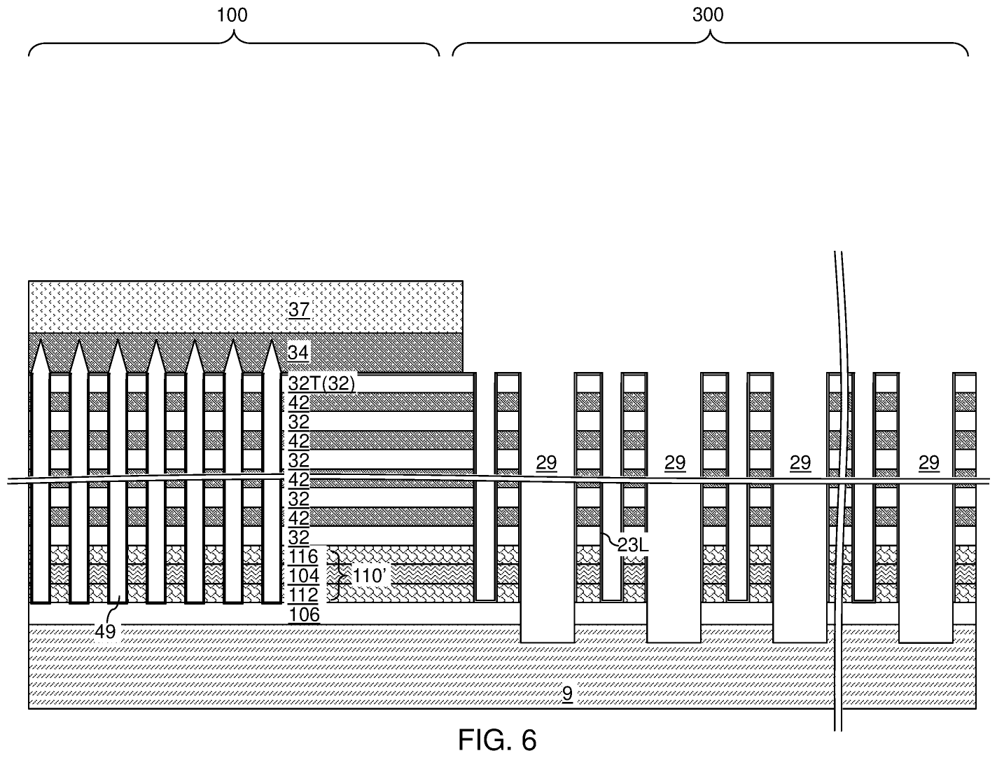

Referring to FIG. 6, a photoresist layer 37 can be applied over the etch mask layer 34, and can be lithographically patterned to cover the memory array region 100 without covering the contact region 300. A reactive ion etch process can be performed to remove portions of the etch mask layer 34 that are not covered by the photoresist layer. The insulating liner layer 23L may be employed as an etch stop layer during the etch process that removes the unmasked portions of the etch mask layer 34. The photoresist layer 37 can be subsequently removed, for example, by ashing.

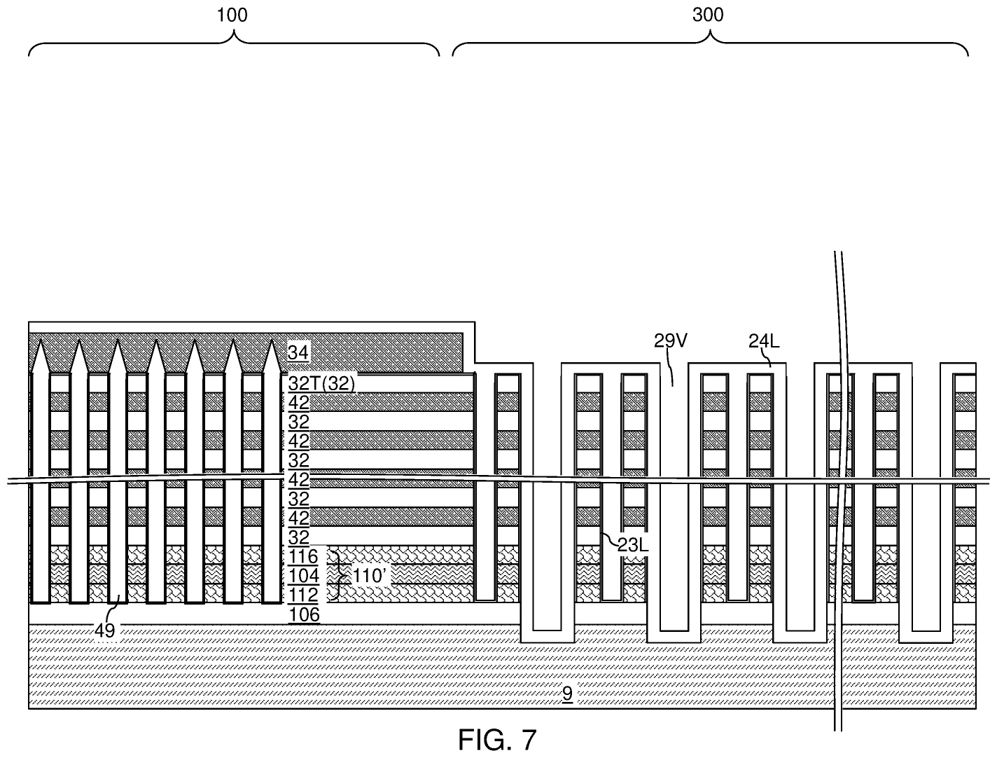

Referring to FIG. 7, a dielectric fill material layer 24L, such as a silicon oxide layer, can be conformally deposited in the support openings 19 and the contact via openings 29. The thickness of the dielectric fill material layer 24L may be greater than one half of the lateral dimension of the support openings 19, and may be less than one half of the lateral dimension of the contact via openings 29. Each support opening 19 can be completely filled with a respective portion of the dielectric fill material layer 24L, while only a peripheral portion of each contact via opening 29 is filled with a respective portion of the dielectric fill material layer 24L. In other words, a vertically-extending void (i.e., cavity) 29V that is not filled with any solid phase material can be present within a volume of each contact via openings 29 after formation of the dielectric fill material layer 24L.

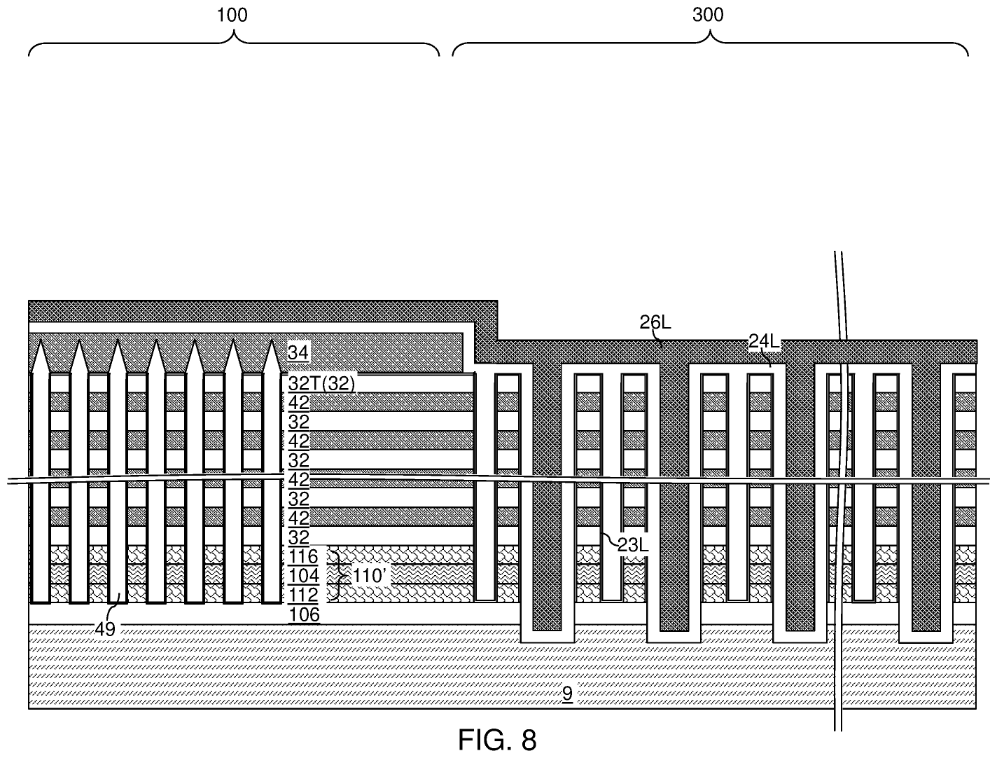

Referring to FIG. 8, a sacrificial fill material layer 26L can be conformally deposited in the volumes of the voids 29V within the contact via openings 29 and over the etch mask layer 34. The sacrificial fill material layer 26L comprises a sacrificial fill material that is different from the material of the dielectric fill material layer 24L. In one embodiment, the sacrificial fill material layer 26L comprises a silicon nitride layer. The thickness of the sacrificial fill material layer 26L can be selected such that the voids 29V within the contact via openings 29 remaining after the processing steps described with reference to FIG. 7 are filled with vertically-extending portions of the sacrificial fill material layer 26L.

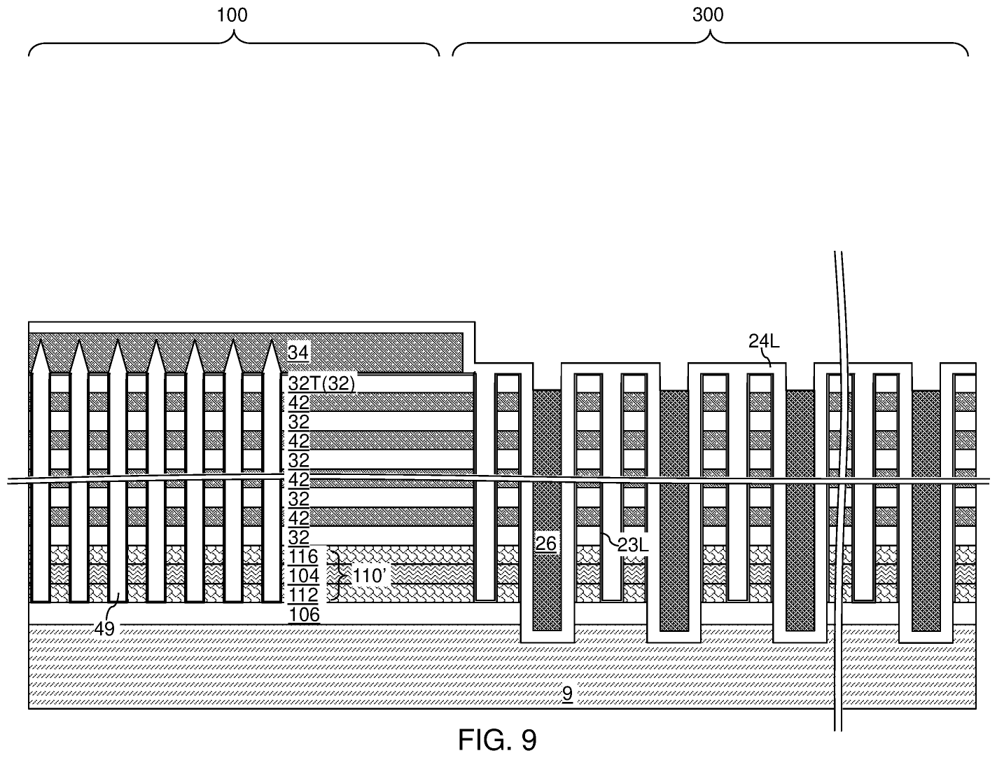

Referring to FIG. 9, a recess etch process can be performed to remove horizontally-extending portions of the sacrificial fill material layer 26L. The recess etch process can be selective to the material of the dielectric fill material layer 24L. For example, if the dielectric fill material layer 24L comprises silicon oxide and if the sacrificial fill material layer 26L comprises silicon nitride, a timed wet etch process employing hot phosphoric acid can be performed to recess the sacrificial fill material layer 26L selective to the material of the dielectric fill material layers 24L. According to an embodiment of the present disclosure, the duration of the recess etch process can be selected such that each remaining vertically-extending portion of the sacrificial fill material layer 26L that is located within a respective one of the contact via openings 29 has a top surface located below the horizontal plane including the topmost surface of the alternating stack (32, 42) (such as the top surface of the topmost insulating layer 32T). Each remaining vertically-extending portion of the sacrificial fill material layer 26L has a pillar shape, and is herein referred to as a sacrificial pillar structure 26. Each sacrificial pillar structure 26 may have a respective straight cylindrical sidewall that vertically extends between a top surface and a bottom surface of the sacrificial pillar structure 26. In one embodiment, the bottom surface of each sacrificial pillar structure 26 may be formed below the horizontal plane including the interface between the carrier substrate 9 and the stopper insulating layer 106.

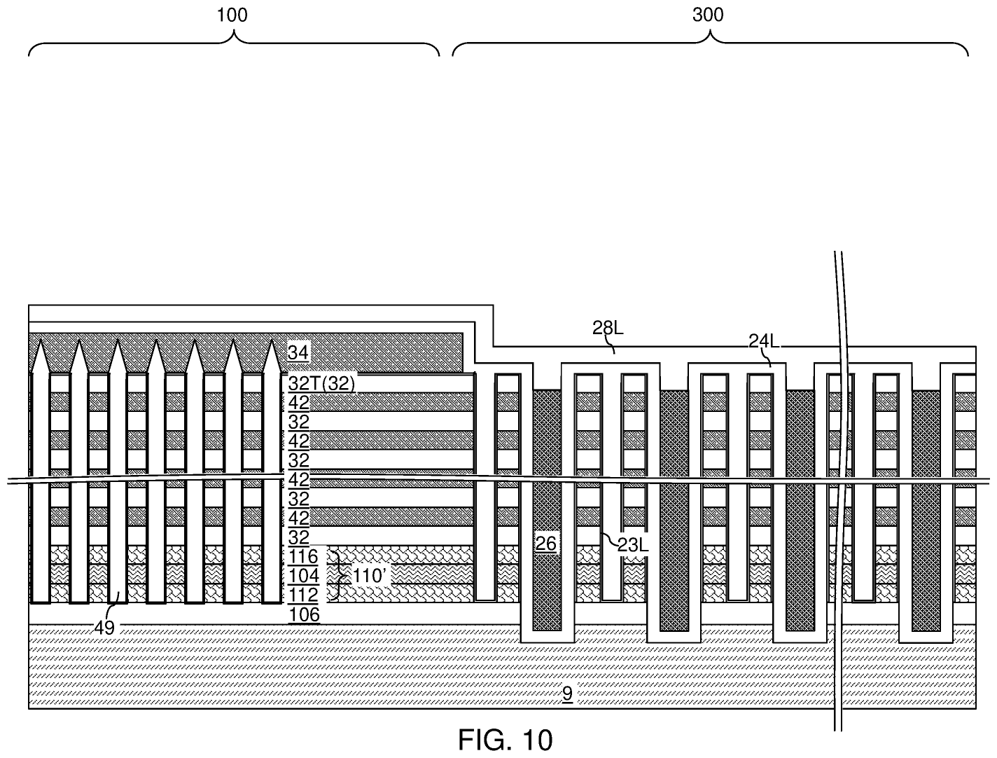

Referring to FIG. 10, an insulating cap layer 28L may be conformally deposited over the sacrificial pillar structures 26. The insulating cap layer 28L comprises an insulating material that is different from the material of the sacrificial material layers 42. In one embodiment, the insulating cap layer 28L may comprise a silicon oxide layer. Each void laterally surrounded by a respective vertically-extending portion of the dielectric fill material layer 24L above a respective sacrificial pillar structure 26 can be filled with a downward-protruding portion of the insulating cap layer 28L.

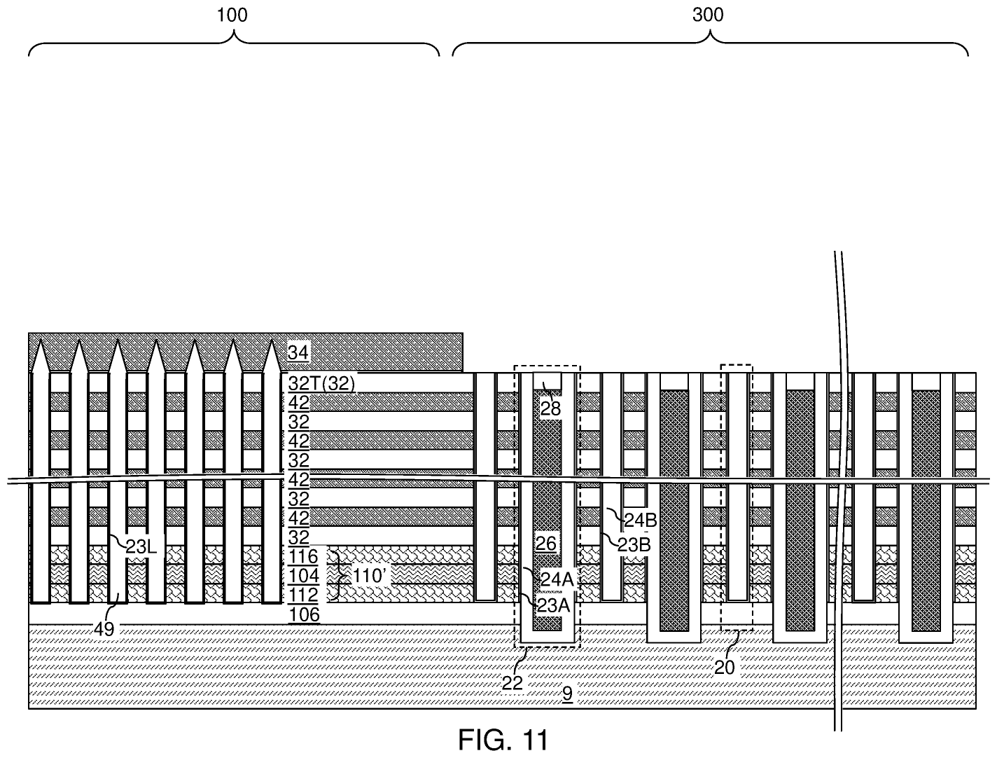

Referring to FIG. 11, the insulating cap layer 28L and the dielectric fill material layer 24L can be partially etched back by performing an etch process. For example, if the insulating cap layer 28L and the dielectric fill material layer 24L comprise silicon oxide, then a wet etch process employing hydrofluoric acid can be performed to remove portions of the insulating cap layer 28L and the dielectric fill material layer 23L that overlies the horizontal plane including the topmost surface of the alternating stack (32, 42). Each remaining portion of the dielectric fill material layer 24L located in a contact via opening 29 constitutes a constitutes a dielectric spacer 24A. Each remaining portion of the dielectric fill material layer 24L located in the support opening 19 constitutes a dielectric pillar portion 24B. Each remaining portion of the insulating cap layer 28L constitutes an insulating cap 28.

A horizontally-extending portion of the insulating liner layer 23L in the contact region 300 can be removed from above the horizontal plane including the topmost surface of the alternating stack (32, 42) after partially etching back the insulating cap layer 28L and the dielectric fill material layer 24L. Each remaining portion of the insulating liner layer 23L that remains in a contact via opening 29 constitutes a contact-via-opening insulating liner 23A. Each remaining portion of the insulating liner layer 23L that remains in a support opening 19 constitutes a support-opening insulating liner 23B.

Each combination of material portions that remains in a support opening 19 constitutes a support pillar structure 20. Thus, each support pillar structure 20 may comprise a combination of a support-opening insulating liner 23B and a dielectric pillar portion 24B. Each combination of material portions that remain in a contact via opening 29 constitutes an in-process assembly 22, or an in-process contact-opening-fill assembly 22. Each in-process assembly 22 may comprise contact-via-opening insulating liner 23A, a dielectric spacer 24A, a sacrificial pillar structure 26, and an insulating cap 28.

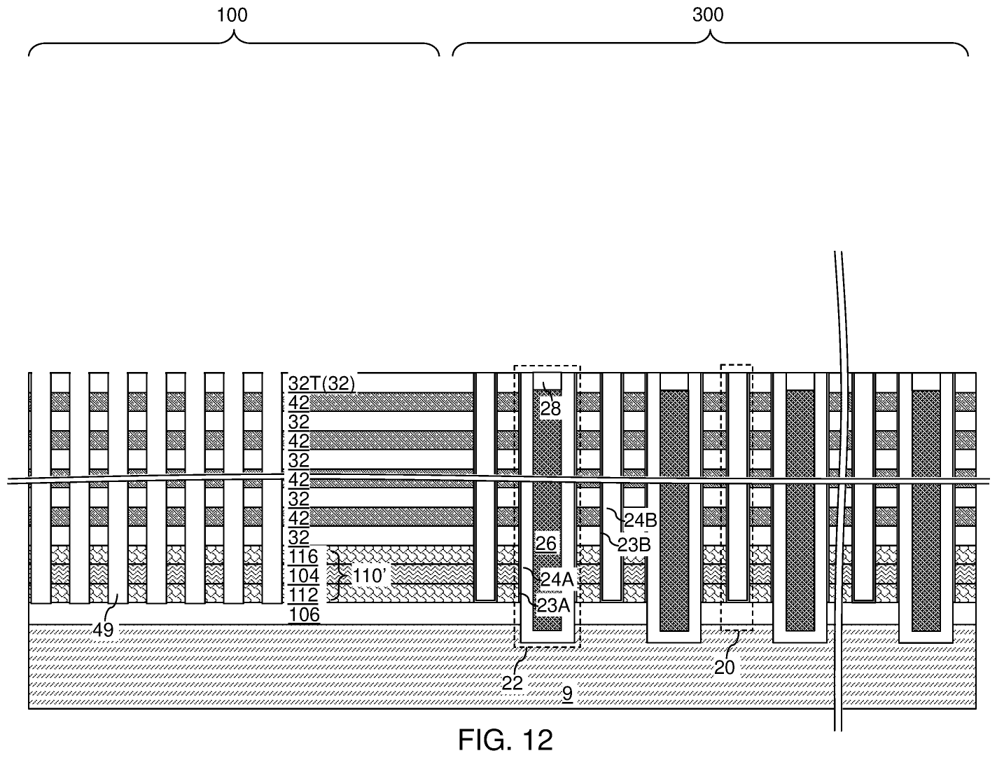

Referring to FIG. 12, the etch mask layer 34 can be removed selective to materials of the topmost insulating layer 32T, the insulating liner layer 23L, the dielectric spacers 24A and the dielectric pillar portions 24B, and the insulating caps 28 by performing a selective etch process. In an illustrative example, the etch mask layer 34 may comprise silicon nitride, and the selective etch process may comprise a wet etch process employing hot phosphoric acid that etches silicon nitride selective to silicon oxide. In another example, the etch mask layer 34 may comprise polysilicon or amorphous silicon, and the selective etch process may comprise a wet etch process employing hot trimethyl-2 hydroxyethyl ammonium hydroxide (“hot TMY”) or tetramethyl aluminum hydroxide (TMAH) that etches silicon selective to silicon oxide. Optionally, the insulating liner layer 23L may be removed after removal of the etch mask layer 34. Alternatively, the insulating liner layer 23L may be employed as a component of a blocking dielectric layer during formation of memory opening fill structures in the memory openings 49.

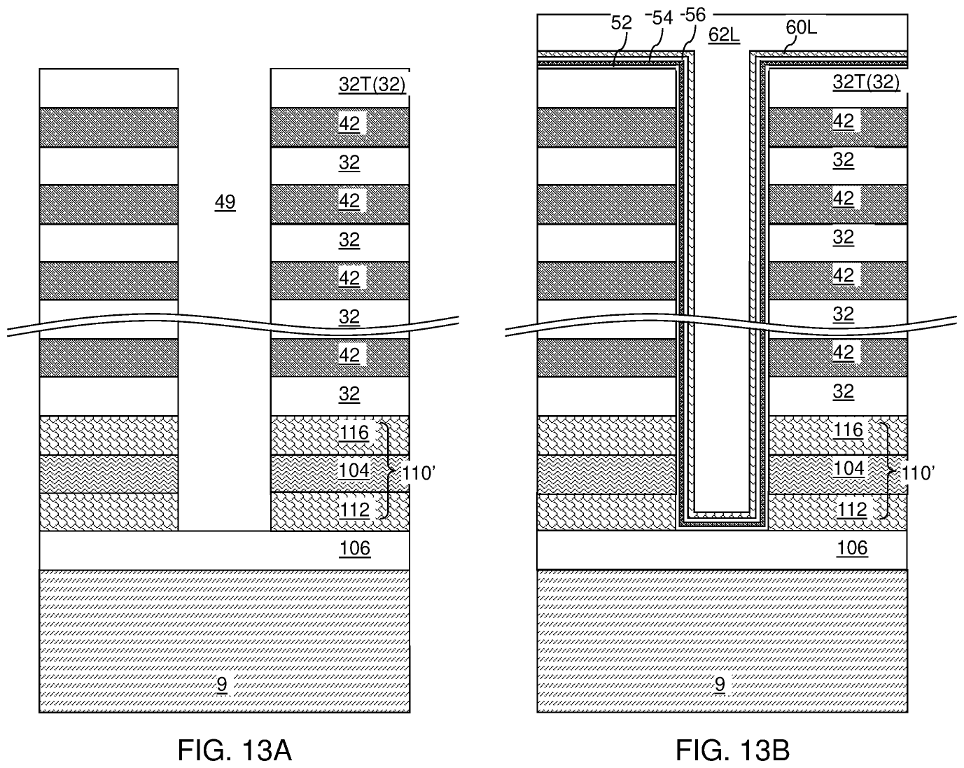

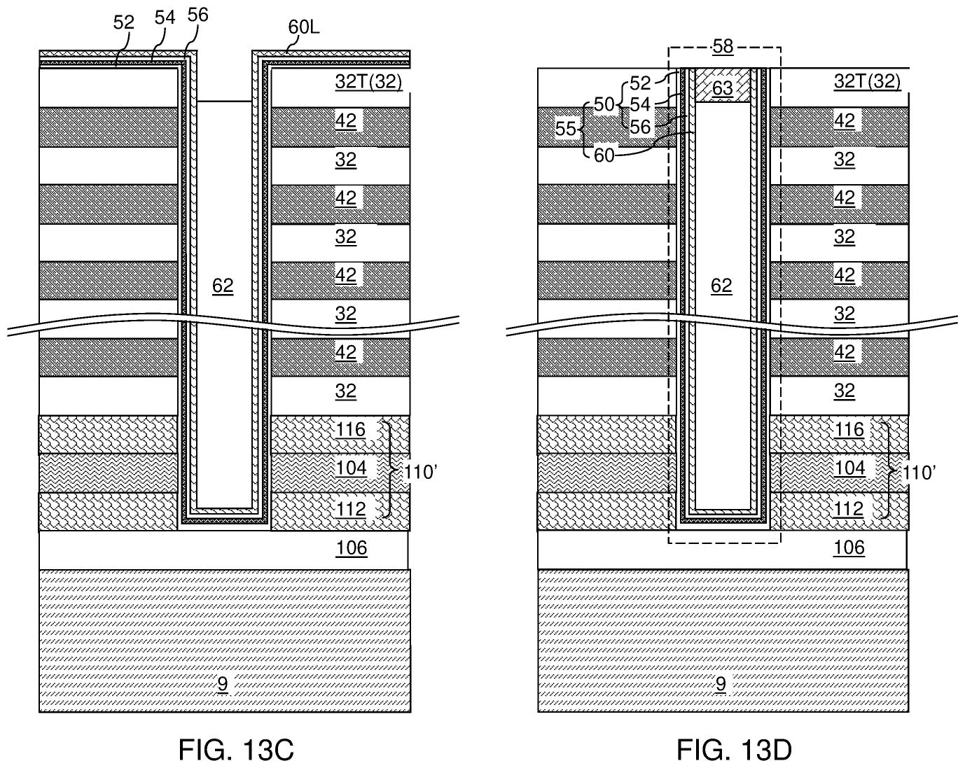

FIGS. 13A-13D are sequential vertical cross-sectional views of a memory opening 49 during formation of a memory opening fill structure 58 according to an embodiment of the present disclosure.

Referring to FIG. 13A, a memory opening 49 is illustrated after the processing steps of FIG. 12.

Referring to FIG. 13B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer. In case the insulating liner layer 23L is not removed at the processing steps of FIG. 13A, the insulating liner layer 23L may be employed as a portion of or as an entirety of the blocking dielectric layer 52.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 13C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 13D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the insulating cap layer 70, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

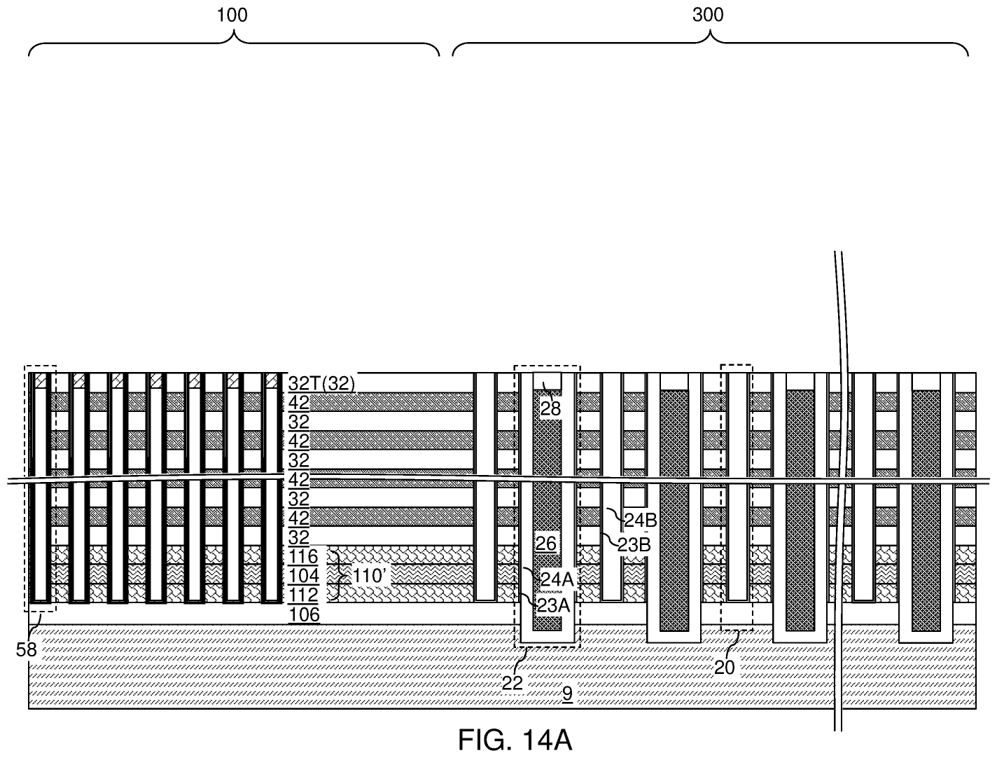

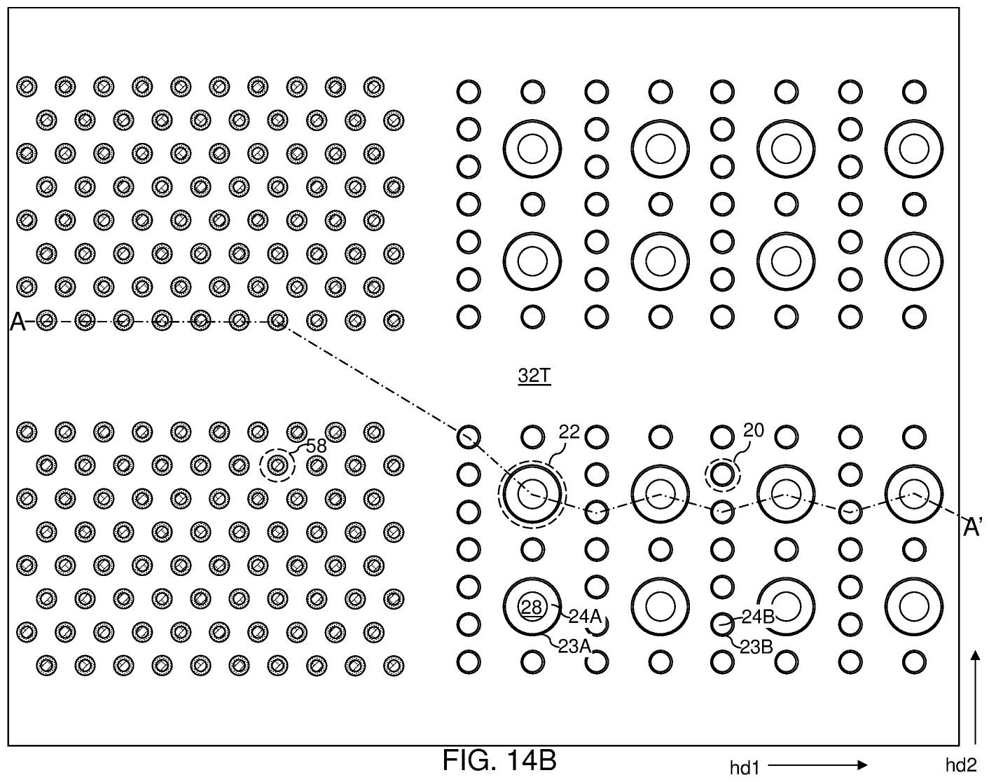

Referring to FIGS. 14A and 14B, the exemplary structure is illustrated after formation of memory opening fill structures 58 within the memory openings 49. Each of the memory opening fill structures 58 may comprise a memory film 50 and a vertical semiconductor channel 60.

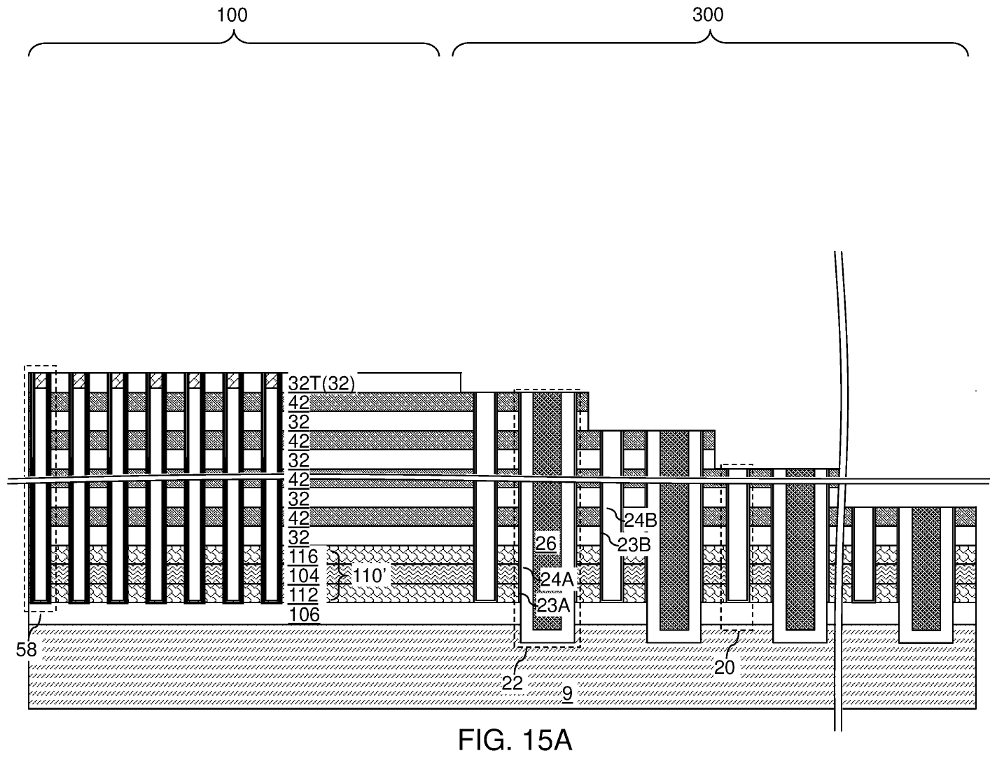

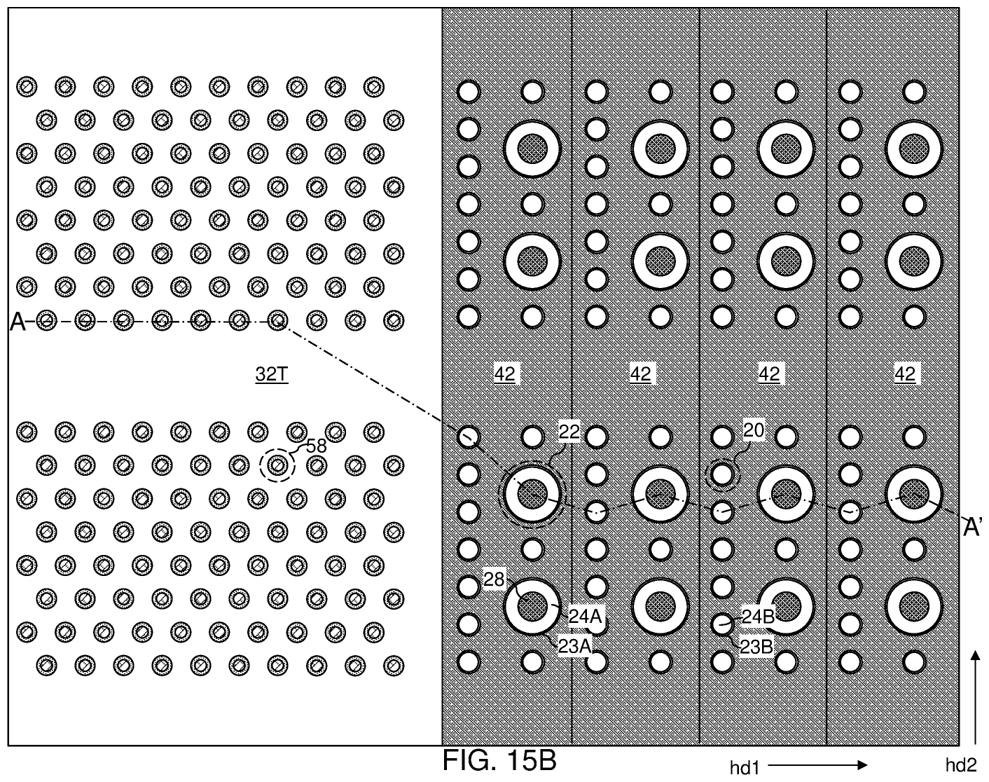

Referring to FIGS. 15A and 15B, stepped surfaces can be formed in the contact region 300 such that vertical steps are formed between neighboring pairs of in-process assemblies 22 that are laterally spaced apart along the first horizontal direction hd1. For example, a trimmable mask layer (not shown) can be formed over the exemplary structure, and a combination of an anisotropic etch process and a mask trimming process can be repeatedly performed to form the stepped surfaces in the contact region 300. The trimmable mask layer may as initially formed may cover the entirety of the memory array region 100 and a predominant fraction of the contact region 300. The trimmable mask layer as initially formed may have an edge that laterally extends along the second horizontal direction hd2 at a location at which a most distal vertical step from an interface between the memory array region 100 and the contact region 300 is to be formed.

Each anisotropic etch process may etch a pair of an insulating layer 32 and a sacrificial material layer 42 within each area that is not covered by the trimmable mask layer. Each mask trimming process may shift an edge of the trimmable mask layer from a location between neighboring pairs of in-process assemblies 22 to another location between adjacent neighboring pairs of in-process assemblies 22 that are more proximal to a boundary between the memory array region 100 and the contact region 300. The memory array region 100 can be covered with the trimmable mask layer throughout the processing steps employed to form the stepped surfaces.

The various components within the in-process assemblies 22 may be recessed at the same etch rate as, or at about the same etch rate as, the insulating layers 32 and the sacrificial material layers 42. The dielectric pillar portions 24B of the support pillar structures 20 can be vertically recessed at the same recess rate as the in-process assemblies 22. If the insulating layers 32, the dielectric spacers 24A, and the dielectric pillar portions 24B comprise silicon oxide and if the sacrificial material layers 42 and the sacrificial pillar structures 26 comprise silicon nitride, each anisotropic etch process may comprise a first etch step that etches silicon oxide selective to silicon nitride by a unit vertical etch distance that is equal to the sum of the thickness of an insulating layer 32 and the thickness of a sacrificial material layer 42, and a second etch step that etches silicon nitride selective to silicon oxide by the unit vertical etch distance. In this case, the in-process assemblies 22 and the support pillar structures 20 can be vertically recessed by the same vertical recess distance as the alternating stack (32, 42), and the stepped surfaces may comprise horizontally-extending surfaces adjoined to vertically-extending surfaces located at vertical steps between neighboring pairs of in-process assemblies 22.

Generally, the stepped surfaces can be formed by patterning the alternating stack (32, 42). The alternating stack (32, 42) has lateral extents that decrease stepwise as a function of a vertical distance from the carrier substrate 9. The in-process assemblies 22 and the support pillar structures 20 can be vertically recessed during patterning of the alternating stack (32, 42) such that the stepped surfaces comprise horizontally-extending surfaces that laterally extend between vertically-extending surfaces located between neighboring pairs of in-process assemblies 22 that are laterally spaced apart along the first horizontal direction hd1, which is the word line horizontal direction that is perpendicular to the boundary between the memory array region 100 and the contact region 300.

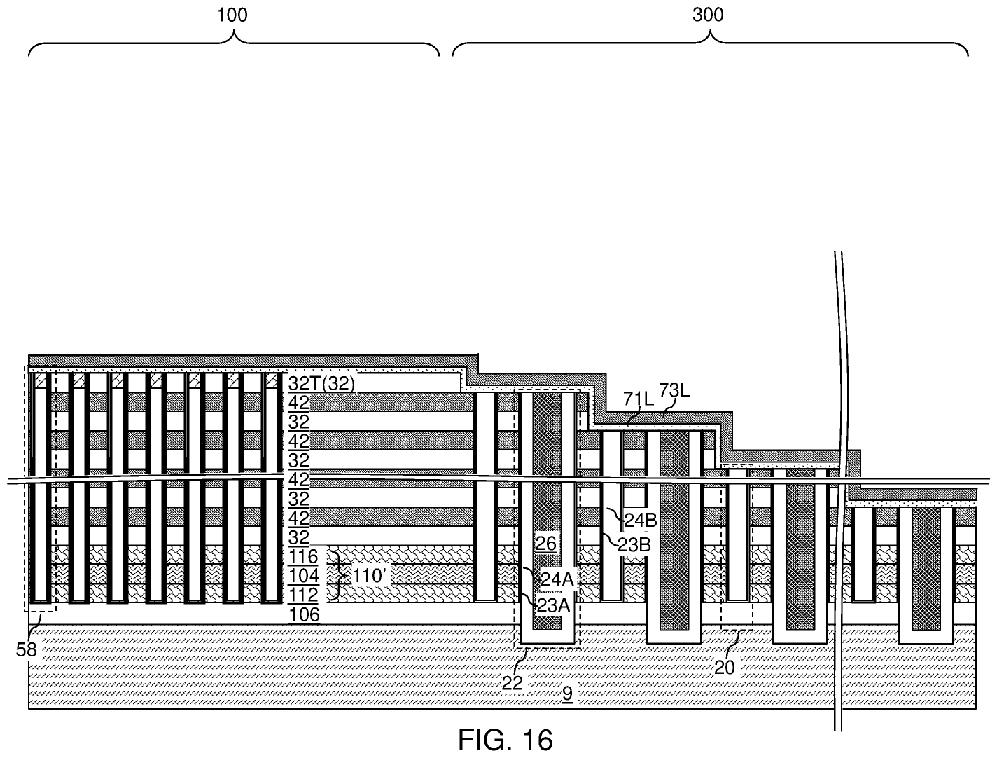

Referring to FIG. 16, a sacrificial etch stop liner layer 71L can be conformally deposited over the stepped surfaces. The sacrificial etch stop liner layer 71L comprises a material having etch resistance to an isotropic etchant to be subsequently employed to remove the sacrificial material layers 42. For example, the sacrificial etch stop liner layer 71L may comprise silicon carbonitride, amorphous silicon, or polysilicon. In one embodiment, the sacrificial etch stop liner layer 71L comprises silicon carbonitride. The thickness of the sacrificial etch stop liner layer 71L may be in a range from 5 nm to 60 nm, such as from 10 nm to 30 nm, although lesser and greater thicknesses may also be employed.

A sacrificial plate material layer 73L can be subsequently deposited over the sacrificial etch stop liner layer 71L. The sacrificial plate material layer 73L comprises a material that can be removed selective to silicon oxide. For example, the sacrificial plate material layer 73L may comprise silicon nitride, a dielectric metal oxide, or a semiconductor material (such as polysilicon or amorphous silicon). The thickness of the sacrificial plate material layer 73L may be in a range from 20 nm to 120 nm, such as from 30 nm to 60 nm, although lesser and greater thicknesses may also be employed.

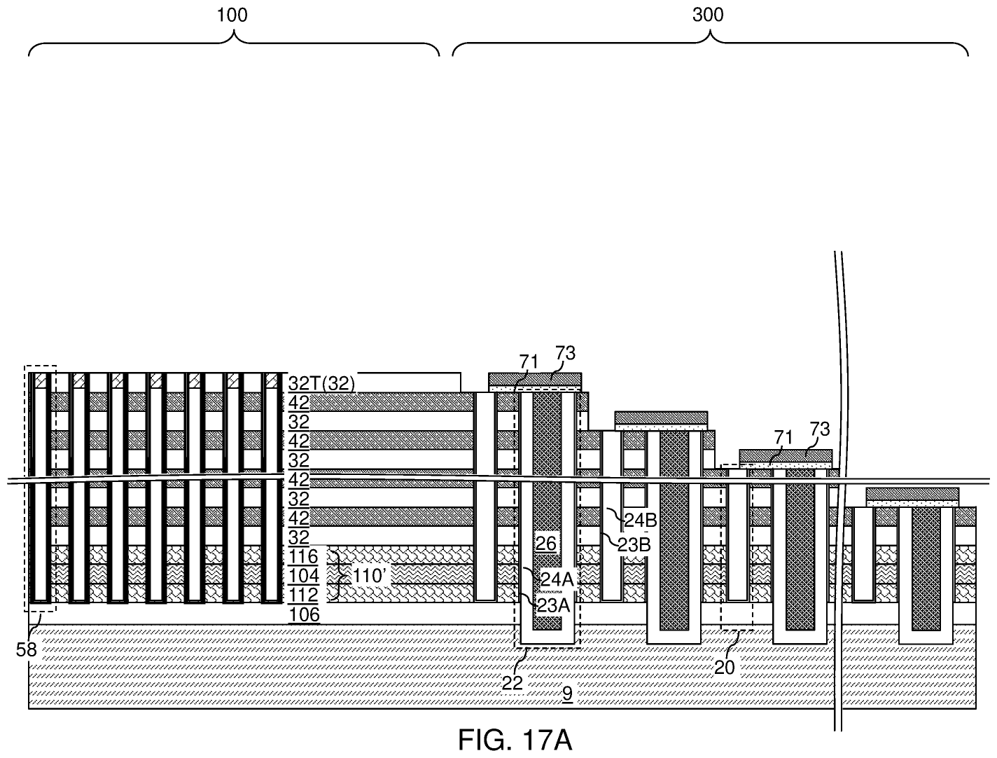

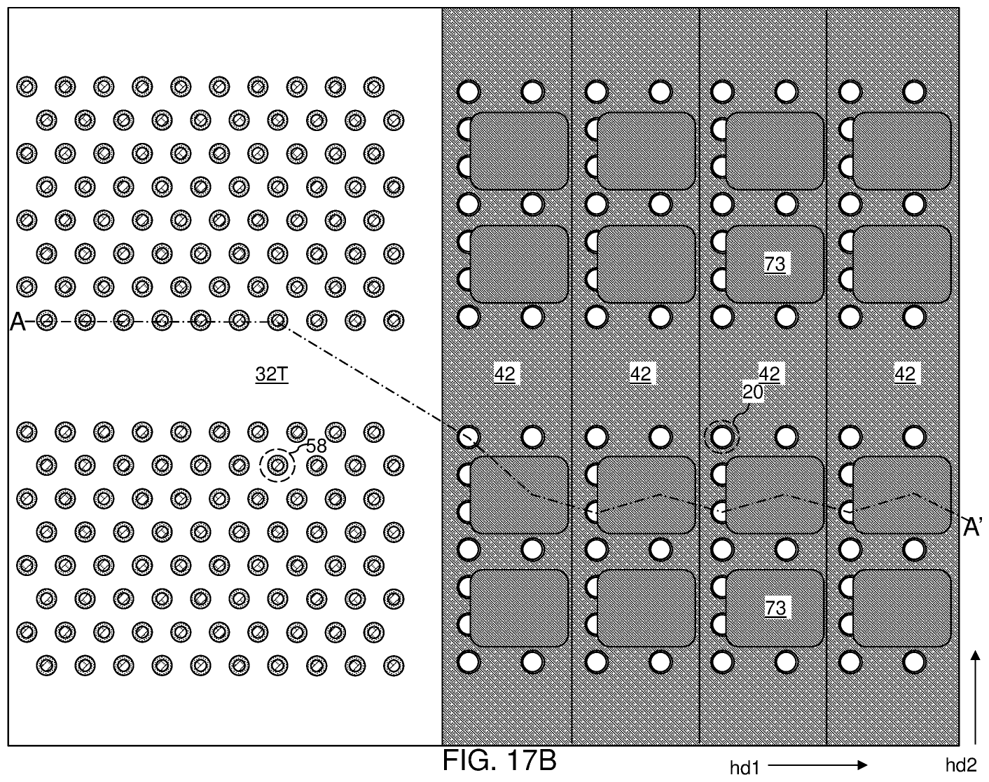

Referring to FIGS. 17A and 17B, a photoresist layer (not shown) can be applied over the sacrificial plate material layer 73L, and can be lithographically patterned to form discrete photoresist material portions. Each discrete photoresist material portion may cover the area of a respective underlying in-process assembly 22, and may have a respective periphery that is laterally offset outward from the sidewall of the respective underlying in-process assembly 22. In other words, each discrete photoresist material portion covers the entirety of the area of a respective underlying in-process assembly 22.

An anisotropic etch process can be performed to remove portions of the sacrificial plate material layer 73L and the sacrificial etch stop liner layer 71L selective to materials of the insulating layers 32 and the sacrificial material layers 42. Each patterned portion of the sacrificial plate material layer 73L constitutes a sacrificial material plate portion 73. Each patterned portion of the sacrificial etch stop liner layer 71L constitutes a sacrificial etch stop liner 71. An array of vertical stacks of a sacrificial etch stop liner 71 and a sacrificial material plate portion 73 can be formed on the horizontally-extending surfaces of the stepped surfaces in the contact region. Each vertical stack of a sacrificial etch stop liner 71 and a sacrificial material plate portion 73 is herein referred to as a sacrificial plate structure (71, 73).

Each sacrificial plate structure (71, 73) is formed over a top surface of a respective in-process assembly 22, and can include a layer stack including a respective sacrificial etch stop liner 71 and a respective sacrificial material plate portion 73. The sidewalls of each sacrificial plate structure (71, 73) can be laterally offset outward from the sidewall(s) of the respective underlying in-process assembly 22. Each sacrificial plate structure (71, 73) can be located entirely between a neighboring pair of vertical surfaces within the stepped surfaces. In one embodiment, at least one of the sacrificial plate structures (71, 73) may contact a top surface of a respective subset of the support pillar structures 20.

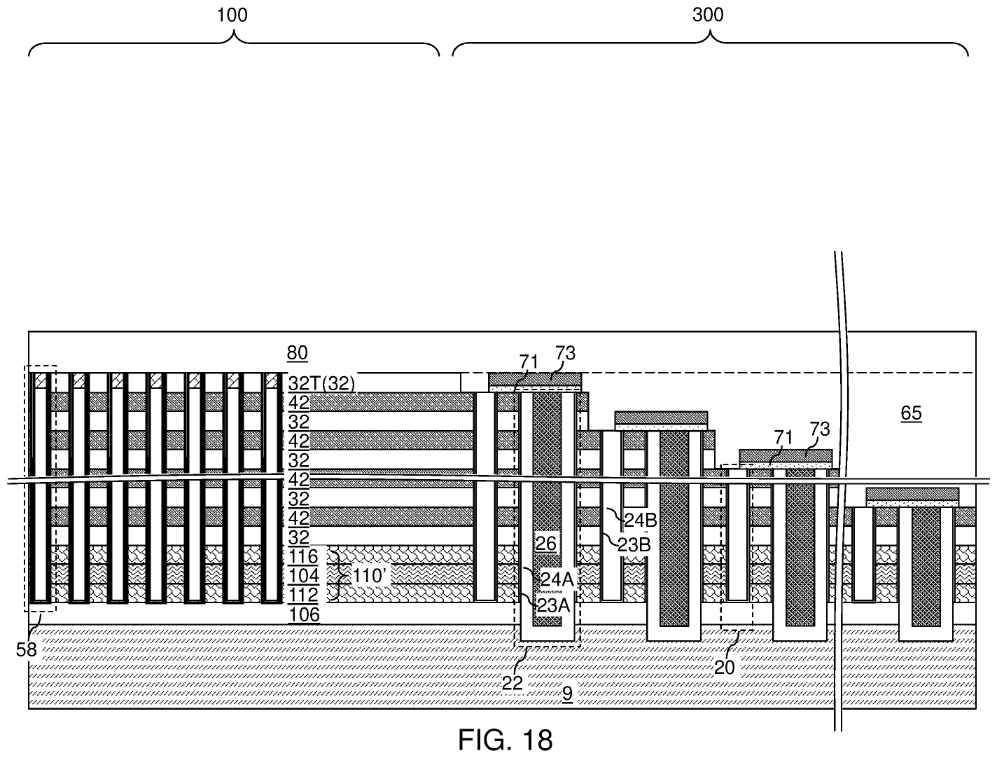

Referring to FIG. 18, a dielectric fill material, such as silicon oxide can be deposited over the stepped surfaces, the array of sacrificial plate structures (71, 73), and the topmost surface of the alternating stack (32, 42). A planarization process can be performed to remove a portion of the dielectric fill material from above a horizontal plane overlying the topmost surface of the alternating stack (32, 42). A recess etch process and/or a chemical mechanical polishing process may be employed for the planarization process. The portion of the dielectric fill material that underlies a horizontal plane including the topmost surface of the alternating stack (32, 42) is herein referred to as a stepped dielectric material portion 65. The portion of the dielectric fill material that overlies the horizontal plane including the topmost surface of the alternating stack (32, 42) is herein referred to as a contact-level dielectric layer 80. The thickness of the contact-level dielectric layer 80 may be in a range from 100 nm to 600 nm, such as from 200 nm to 400 nm, although lesser and greater thicknesses may also be employed.

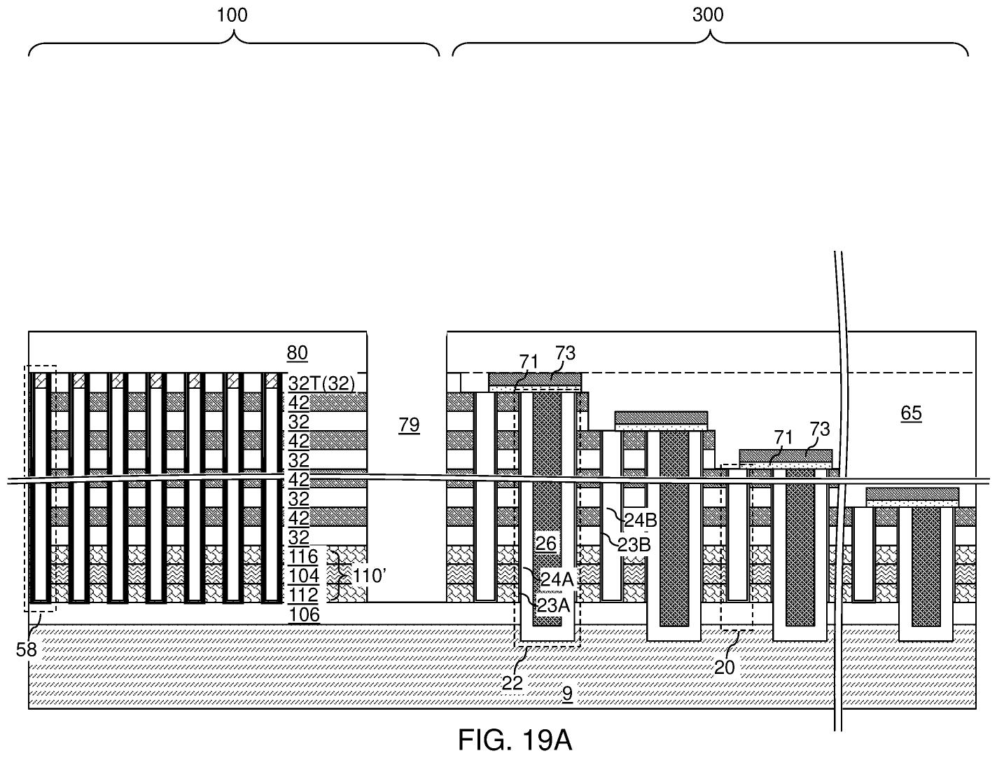

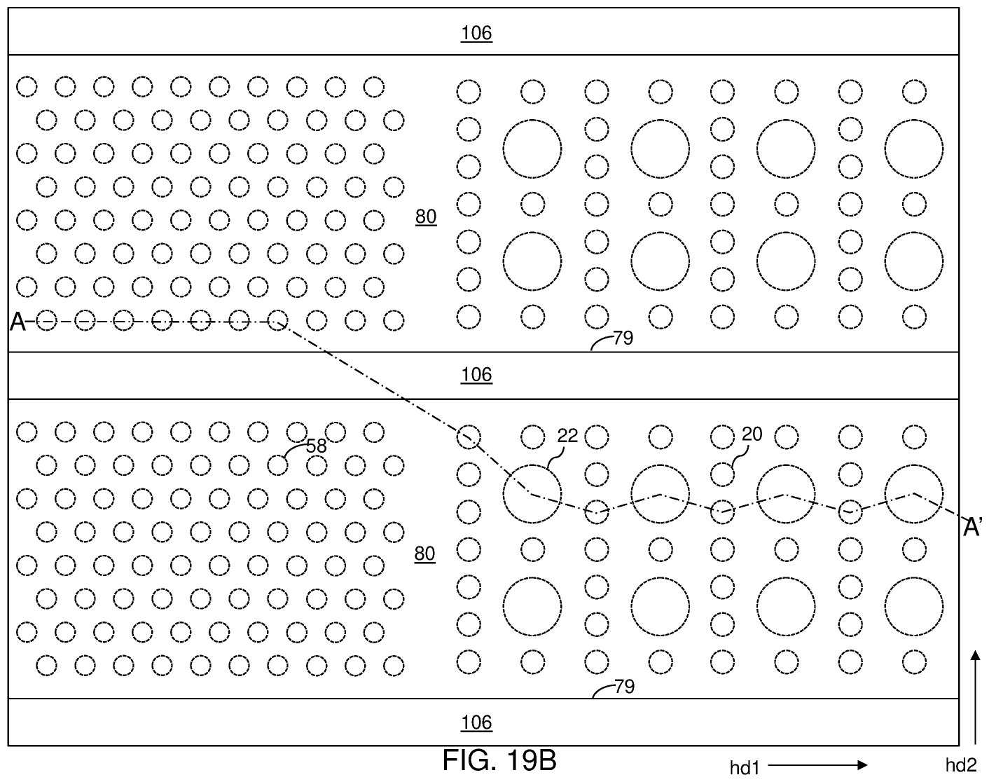

Referring to FIGS. 19A and 19B, a photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the stepped dielectric material portion 65, and the in-process source-level material layers 110′. Lateral isolation trenches 79 laterally extending along the first horizontal direction hd1 can be formed through the alternating stack (32, 42), the stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The photoresist layer can be subsequently removed, for example, by ashing.

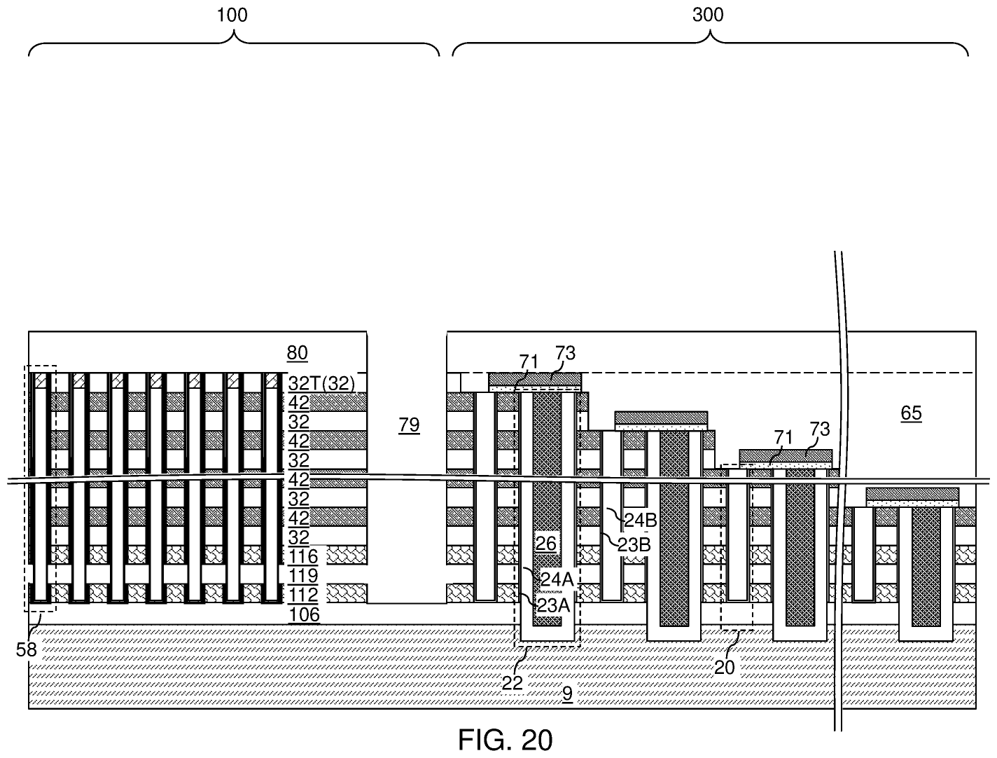

Referring to FIG. 20, an etchant that etches the material of the source-level sacrificial layer 104 selective to the materials of the alternating stack (32, 42), the contact level dielectric layer 80, the stepped dielectric material portion 65, the lower source-level semiconductor layer 112, the upper source-level semiconductor layer 116, the upper sacrificial liner (if present; not shown), and the lower sacrificial liner (if present; not shown) may be introduced into the lateral isolation trenches 79 by performing an isotropic etch process. For example, if the source-level sacrificial layer 104 includes undoped amorphous silicon or polysilicon, then a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact level dielectric layer 80, the stepped dielectric material portion 65, the lower source-level semiconductor layer 112, and the upper source-level semiconductor layer 116. A source cavity 109 is formed in the volume from which the source-level sacrificial layer 104 is removed.

Each of the memory opening fill structures 58 is physically exposed to the source cavity 109. Specifically, each of the memory opening fill structures 58 includes a sidewall that is physically exposed to the source cavity 109.

A sequence of isotropic etchants, such as wet etchants, may be applied through the source cavity 109 to the physically exposed portions of the memory films 50 to sequentially etch the various component layers of the memory films 50 from outside to inside, and to physically expose cylindrical surfaces of the vertical semiconductor channels 60 at the level of the source cavity 109. The upper and lower sacrificial liners (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. Thus, the source cavity 109 is formed by isotropically etching the source-level sacrificial layer 104 and a bottom sidewall portion of each of the memory films 50 selective to at least one source-level semiconductor layer (such as the lower source-level semiconductor layer 112 and the upper source-level semiconductor layer 116) and the vertical semiconductor channels 60.

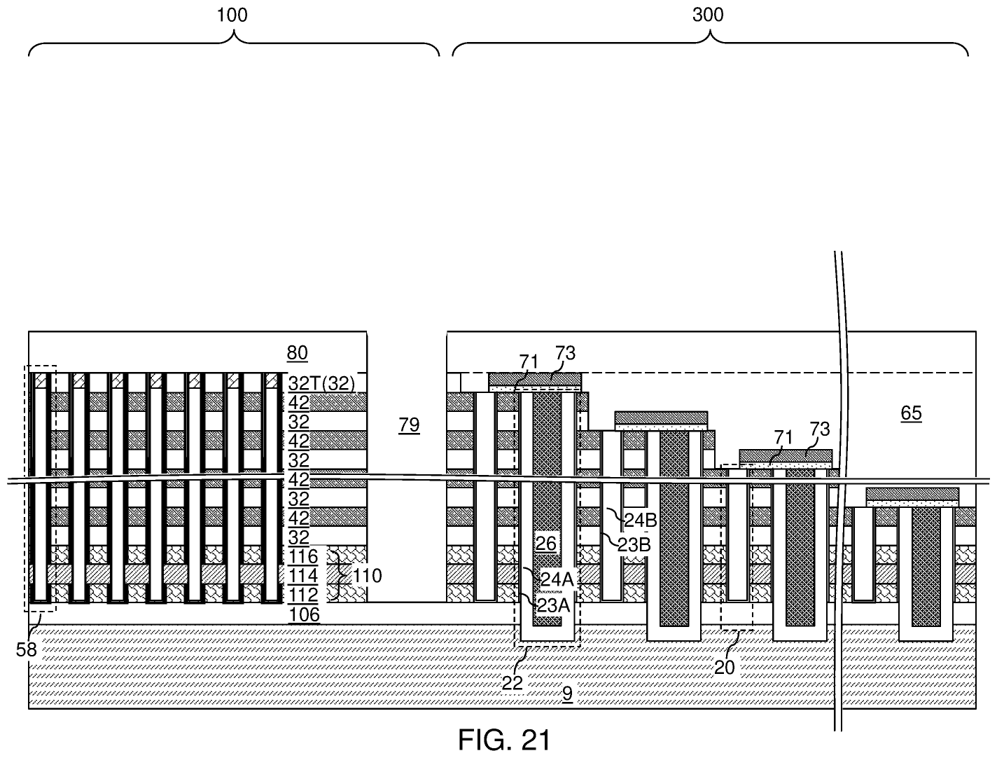

Referring to FIG. 21, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112).

In one embodiment, the doped semiconductor material of the second conductivity type may be deposited on the physically exposed semiconductor surfaces around the source cavity 109 by a selective semiconductor deposition process. The deposited doped semiconductor material forms a source contact layer 114, which contacts sidewalls of the vertical semiconductor channels 60. The atomic concentration of the dopants of the second conductivity type in the deposited semiconductor material may be in a range from 1.0×10¹⁹/cm³ to 2.0×10²¹/cm³, such as from 2.0×10¹⁹/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to form a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

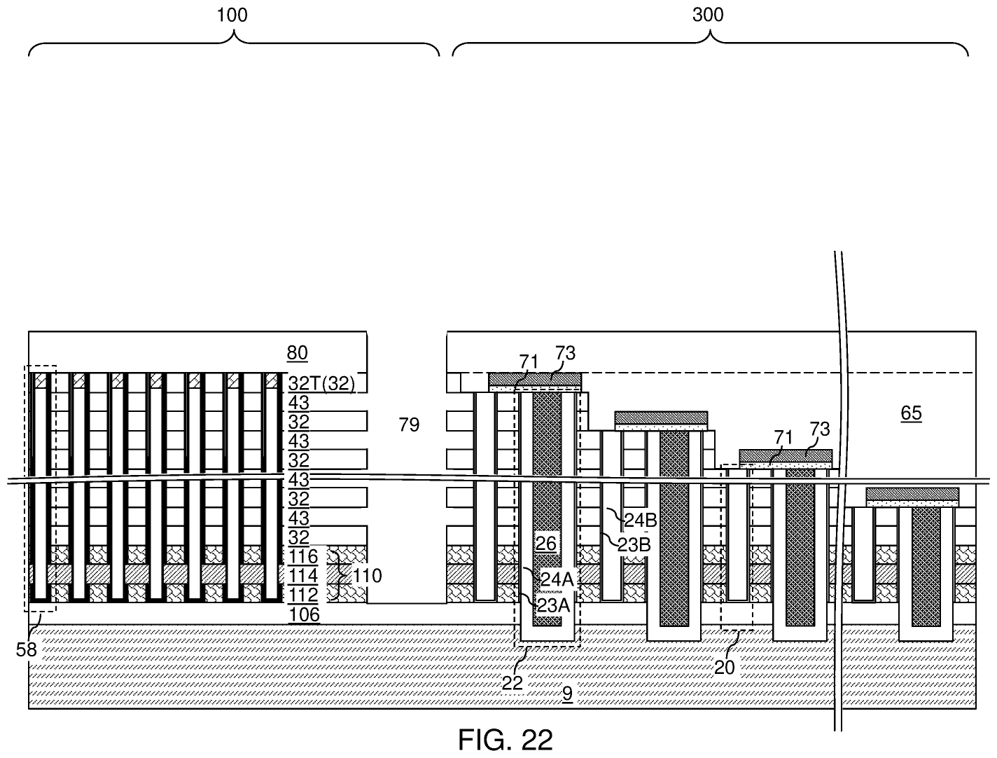

Referring to FIG. 22, an isotropic etch process can be performed through the trenches 79 to remove the sacrificial material layers 42 selective to the insulating layers 32, the stopper insulating layer 106, the memory opening fill structures 58, the sacrificial etch stop liners 71, and the source layer 110. Lateral recesses 43 can be formed in volumes from which the sacrificial material layers 42 are removed. Sidewall surface segments of the memory opening fill structures 58 can be physically exposed to the lateral recesses 43. In an illustrative example, if the sacrificial material layers 42 comprise silicon nitride, then the isotropic etch process may comprise a wet etch process employing hot phosphoric acid.

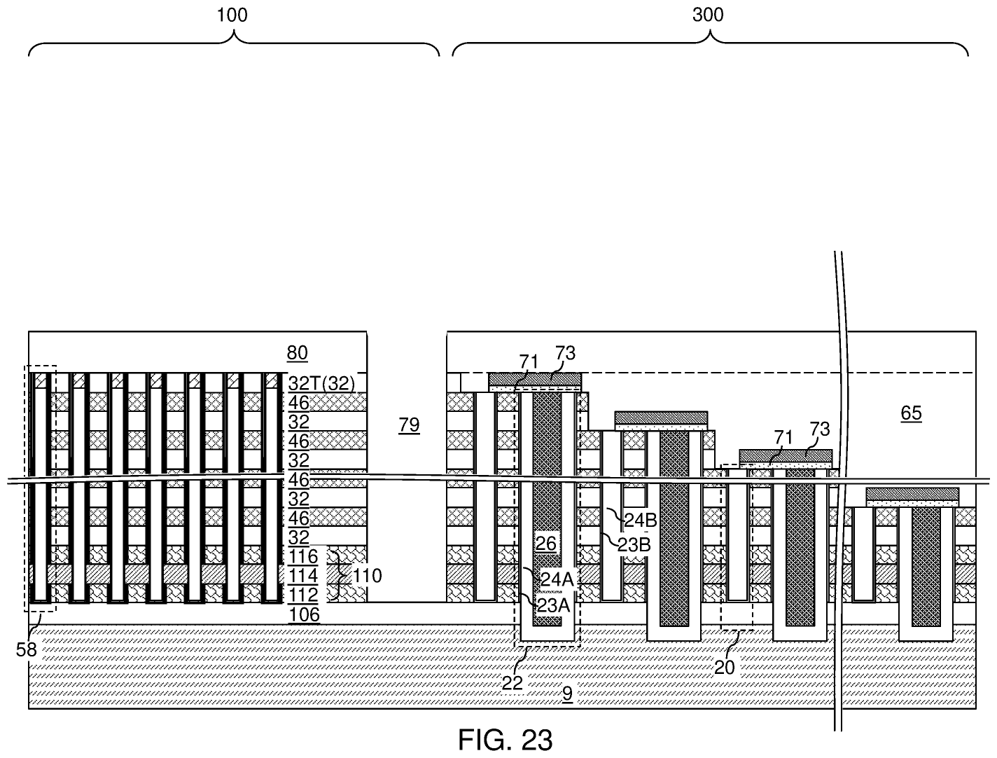

Referring to FIG. 23, an optional backside blocking dielectric layer (not shown) can be optionally formed in the lateral recesses 43 by a conformal deposition process. At least one conductive material, such as at least one metallic material, can be conformally deposited in the lateral recesses 43. The at least one conductive material may comprise, for example, a combination of a metallic barrier material and a metallic fill material. The metallic barrier material may comprise, for example, TiN, TaN, WN, MON, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the lateral recesses 43 constitutes an electrically conductive layer 46. An alternating stack of insulating layers 32 and electrically conductive layers 46 can be formed between each neighboring pair of lateral isolation trenches 79 over the carrier substrate 9. A plurality of alternating stacks of insulating layers 32 and electrically conductive layers 46 can be laterally spaced apart from each other by the lateral isolation trenches 79.

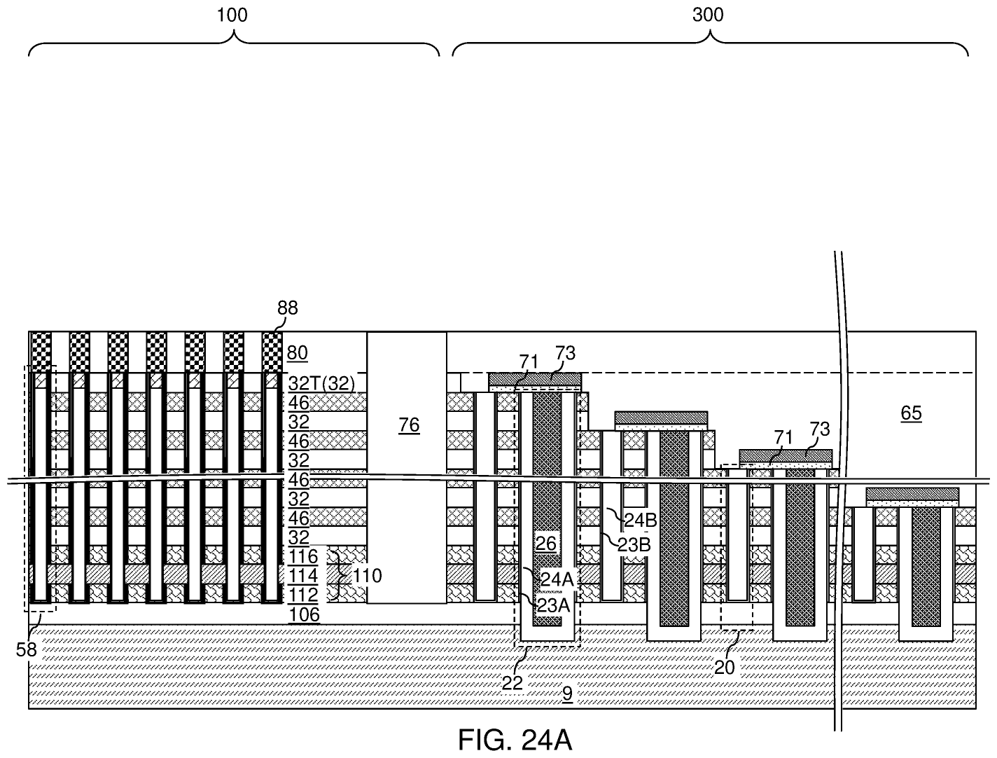

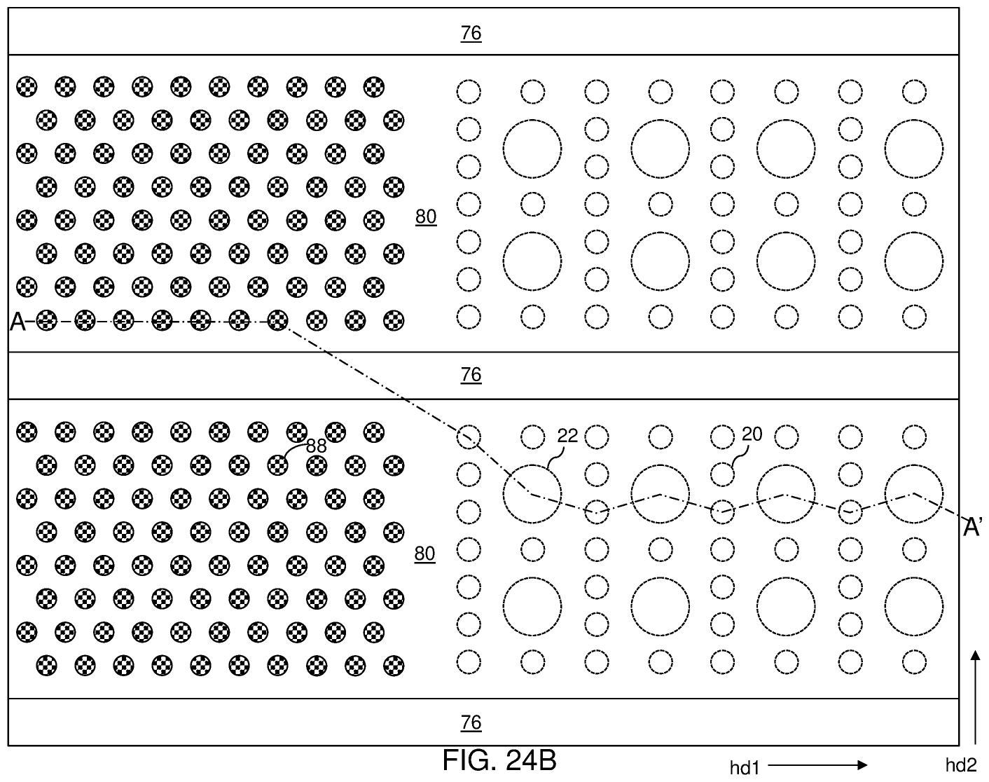

Referring to FIGS. 24A and 24B, an insulating material is deposited in the lateral isolation trenches 79. The insulating material constitutes an isolation trench fill structure 76 that fills a respective lateral isolation trench 79.

A photoresist layer (not shown) can be applied over the contact-level dielectric layer 80, and can be lithographically patterned to form openings over each of the memory opening fill structures 58. An anisotropic etch process can be performed to transfer the pattern of the openings in the photoresist layer through the contact-level dielectric layer 80. Drain contact via cavities can be formed through the contact-level dielectric layer 80 over the memory opening fill structures 58. The photoresist layer can be subsequently removed, for example, by ashing.

At least one conductive material, such as a combination of a metallic barrier material and a metallic fill material, can be deposited in the drain contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63.

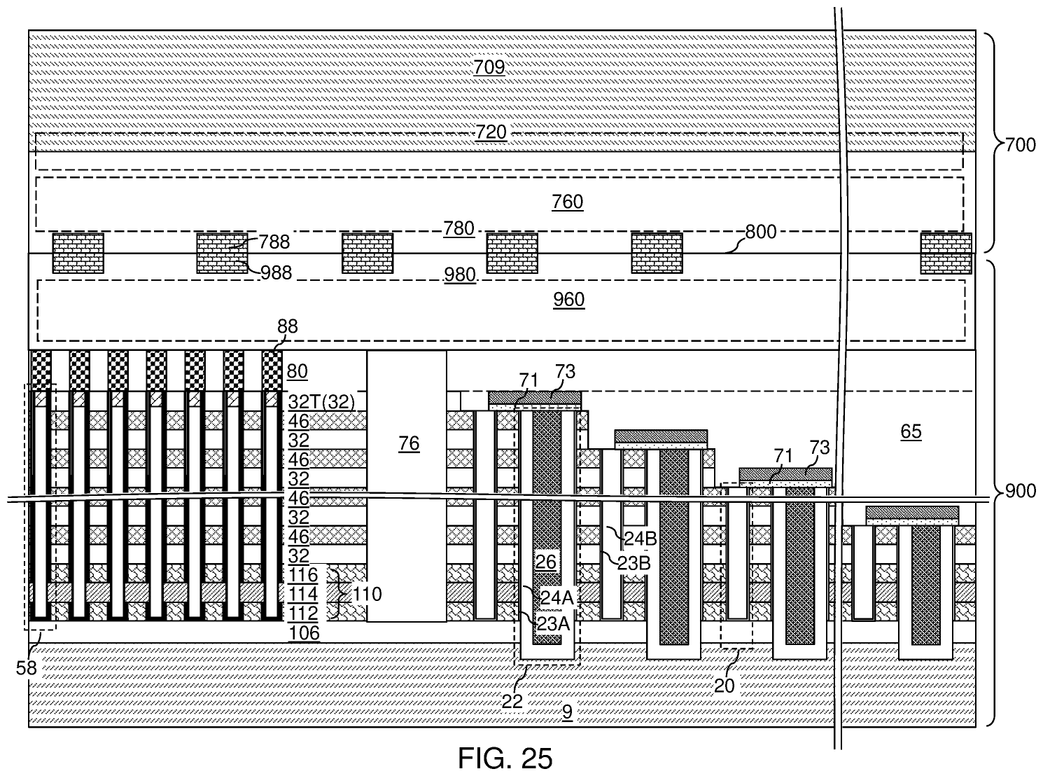

Referring to FIG. 25, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures (e.g., bit lines), and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array, such as the bit lines and the drain regions 63 of the memory opening fill structures 58.

A memory die 900 is thus formed which comprises the memory-side dielectric material layers 960 formed over the alternating stacks (32, 46), the memory-side metal interconnect structures 980 embedded in the memory-side dielectric material layers 960, and the memory-side bonding pads 988 embedded within the memory-side dielectric material layers 960, and specifically, within the topmost layer of the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60, and a two-dimensional array of contact via structures (such as the drain contact via structures 88) overlying the three-dimensional memory array and electrically connected to a respective one of the vertical semiconductor channels 60 via the respective drain regions 63.

Additionally, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source structure to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 788 to the memory-side bonding pads 988 at a bonding interface 800. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

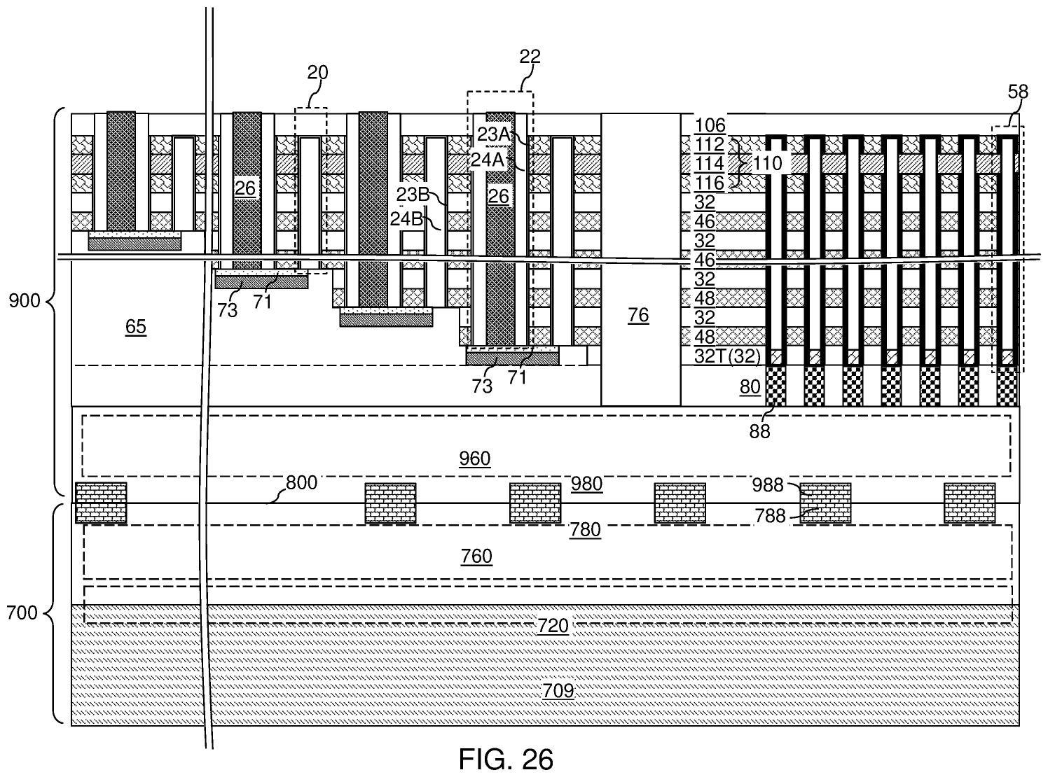

Referring to FIG. 26, the carrier substrate 9 can be removed, for example, by grinding, polishing, cleaving, an isotropic etch process, and/or an anisotropic etch process. If a polishing process, such as a chemical mechanical polishing process, is employed to remove the carrier substrate 9, then the stopper material layer 106 may be subsequently employed as a polishing stopper material layer. If an etch process, such as a wet etch process, is employed to remove the carrier substrate 9, them the stopper material layer 106 may be subsequently employed as an etch stop material layer. Backside end surfaces of the sacrificial pillar structures 26 can be physically exposed upon removal of the carrier substrate 9. Further, annular backside end surfaces of the dielectric spacers 24A can be physically exposed upon removal of the carrier substrate 9.

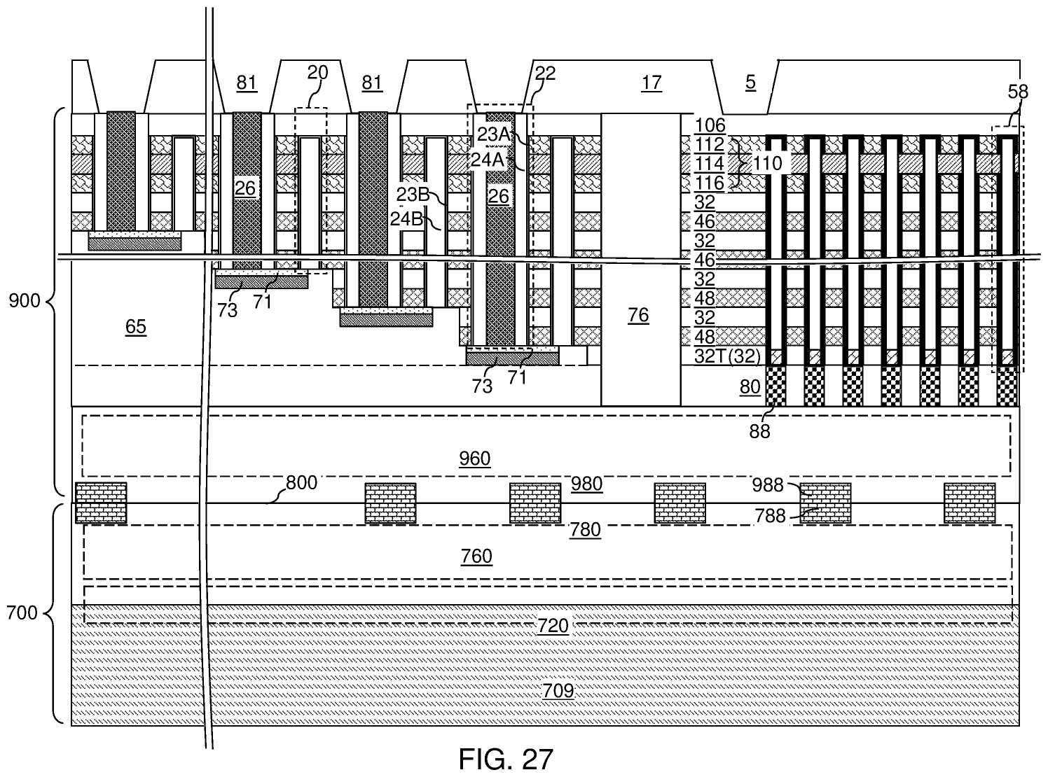

Referring to FIG. 27, at least one backside dielectric layer 17 can be subsequently deposited over the stopper insulating layer 106. Optionally, backside metal interconnect structures (not shown) may be formed within the at least one backside dielectric layer 17. If present, the backside metal interconnect structures may comprise backside metal line structures and/or backside metal via structures.

A photoresist layer (not shown) can be applied over the backside of the at least one backside dielectric layer 17, and can be lithographically patterned to form openings over the sacrificial pillar structures 26 and over an area of the source layer 110. An anisotropic etch process can be performed to transfer the pattern of the openings through the at least one backside dielectric layer 17. Layer-contact backside openings 81 can be formed over the sacrificial pillar structures 26, and at least one source-contact backside opening 5 can be formed outside the area of the sacrificial pillar structures 26. The photoresist layer can be subsequently removed, for example, by ashing.

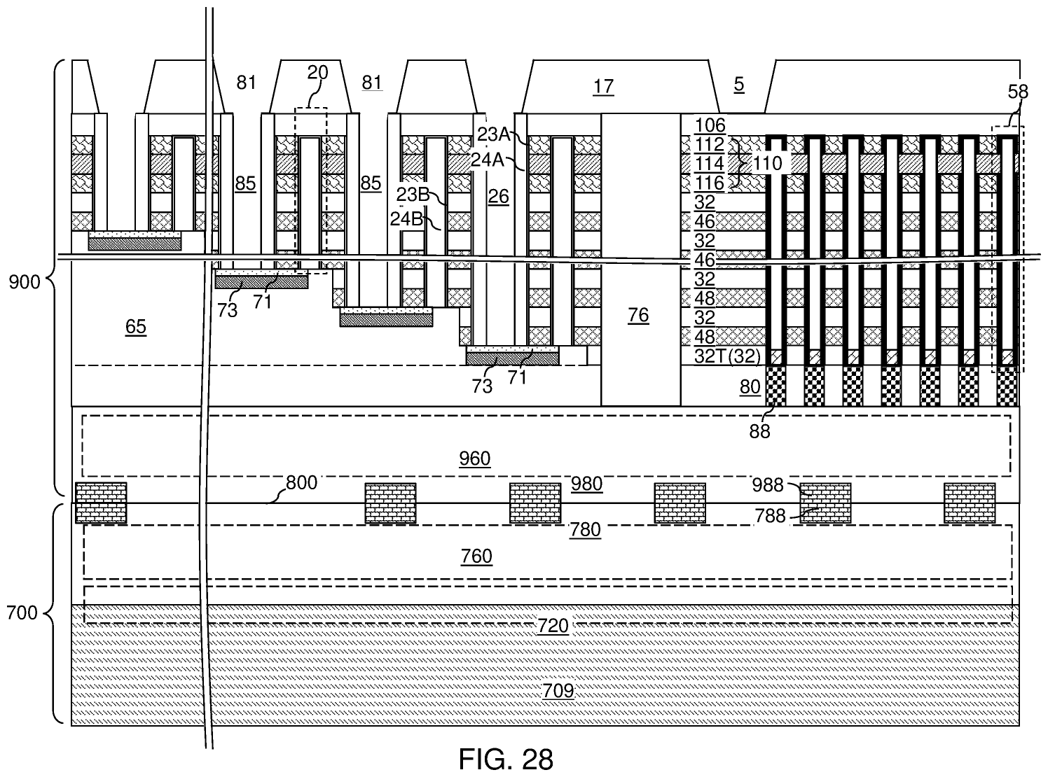

Referring to FIG. 28, a first isotropic etch process can be performed to remove the sacrificial pillar structures 26 selective to the materials of the stopper insulating layer 106, the dielectric spacers 24A, and the sacrificial etch stop liners 71. For example, if the sacrificial pillar structures 26 comprise silicon nitride, a wet etch process employing hot phosphoric acid can be performed to remove the sacrificial pillar structures 26 without removing the stopper insulating layer 106, the dielectric spacers 24A, and the sacrificial etch stop liners 71. Contact via cavities 85 can be formed in the volumes from which the sacrificial pillar structures 26 are removed.

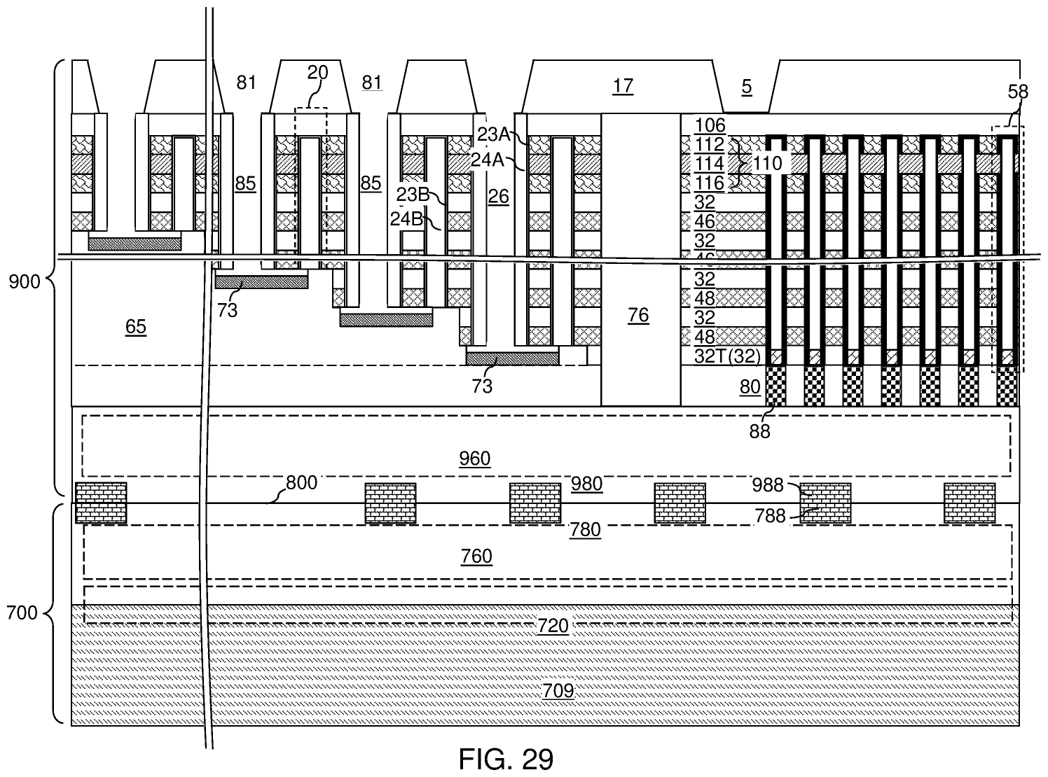

Referring to FIG. 29, the sacrificial etch stop liners 71 can be removed selective to the materials of the stopper insulating layer 106, the dielectric spacers 24A, the insulating layers 32, the sacrificial material plate portions 73, and the stepped dielectric material portion 65. The contact via cavities 85 can be expanded to include the volumes from which the sacrificial etch stop liners 71 are removed.

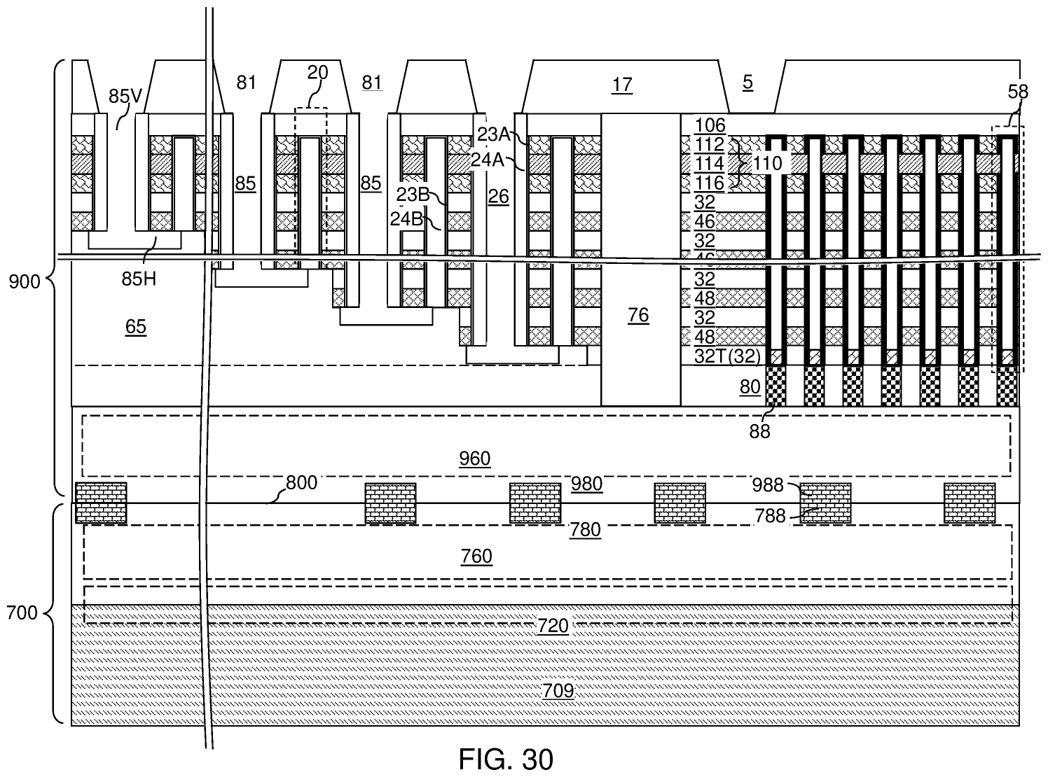

Referring to FIG. 30, a second isotropic etch process can be performed to remove the sacrificial material plate portions 73 selective to the materials of the stopper insulating layer 106, the dielectric spacers 24A, the insulating layers 32, and the stepped dielectric material portion 65. For example, if the sacrificial material plate portions 73 comprise silicon nitride, then a wet etch process employing hot phosphoric acid can be performed to remove the sacrificial material plate portions 73 without removing the stopper insulating layer 106, the dielectric spacers 24A, the insulating layers 32, and the stepped dielectric material portion 65. The contact via cavities 85 can be expanded to include the volumes from which the sacrificial material plate portions 73 are removed. Each of the electrically conductive layers 46 can have a respective horizontal surface segment that is physically exposed to a horizontally-extending portion 85H of a respective one of the contact via cavities 85. A subset of the dielectric pillar structures 20 can have end surfaces that are physically exposed to the contact via cavities 85. Each of the contact via cavities 85 can include a respective vertically-extending portion 85V and a respective horizontally-extending portion 85H. The vertically-extending portions 85V of the contact via cavities 85 can have different vertical extents, and the horizontally-extending portions 85H of the contact via cavities 85 can be located at different levels and can be vertically spaced apart from each other.

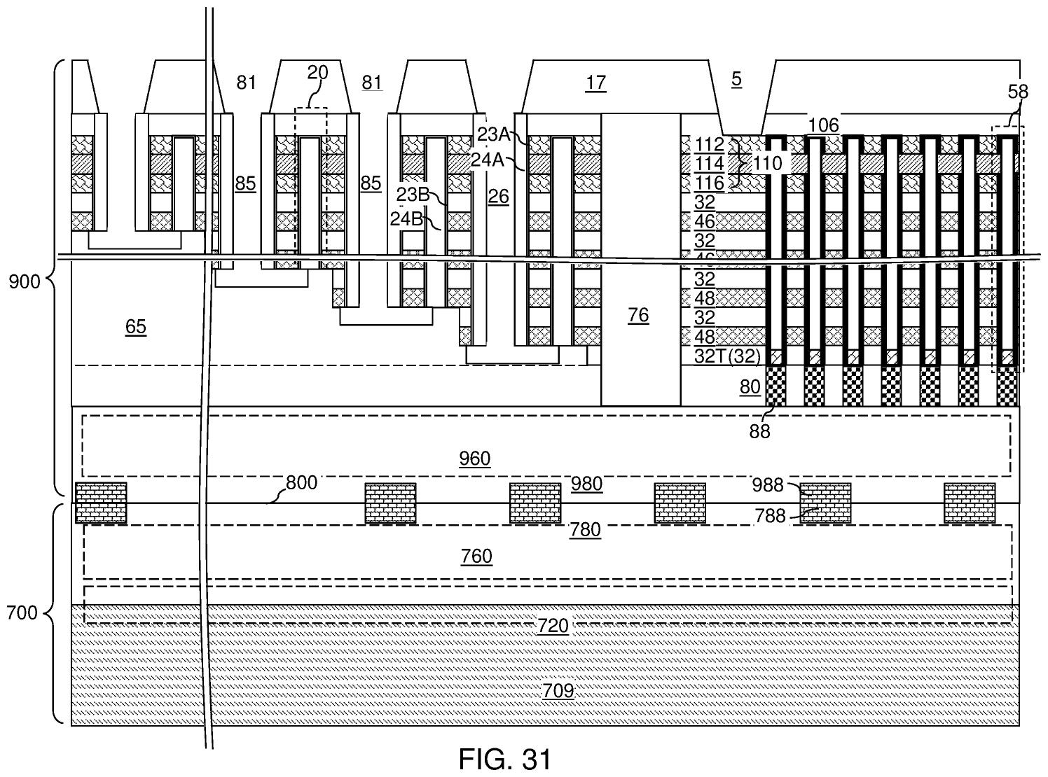

Referring to FIG. 31, a photoresist layer (not shown) can be applied over the backside of the at least one backside dielectric layer 17, and can be lithographically patterned form an opening around the at least one source-contact backside opening 5. An anisotropic etch process can be performed to vertically extend the at least one source-contact backside opening 5 through the stopper insulating layer 106. A backside surface of the source layer 110 can be physically exposed underneath the at least one source-contact backside opening 5. The photoresist layer can be subsequently removed, for example, by ashing.

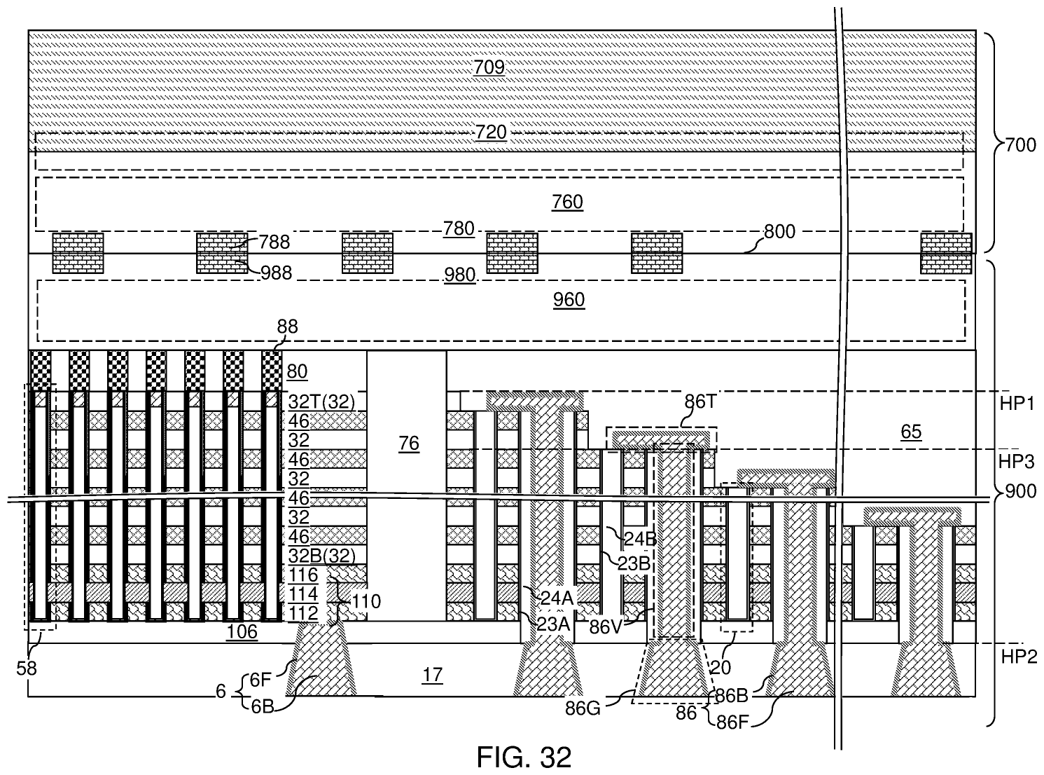

Referring to FIG. 32, a metallic barrier liner layer can be conformally deposited on the physically exposed surfaces around the contact via cavities 85, the layer-contact backside openings 81, and optionally the at least one source-contact backside opening 5. The metallic barrier liner layer comprises a conductive metallic barrier material, such as TiN, TaN, WN, MON, TiC, TaC, and/or WC. The metallic barrier liner layer can be deposited by a conformal deposition process such as a chemical vapor deposition process. The thickness of the metallic barrier liner layer may be in a range from 5 nm to 30 nm, although lesser and greater thicknesses may also be employed.

A metallic fill material can be deposited in remaining volumes of the contact via cavities 85, the layer-contact backside openings 81, and the at least one source-contact backside opening 5. The metallic fill material may comprise W, Co, Ru, Mo, Ti, Ta, Cu, or combinations thereof. The metallic fill material may be conformally deposited by a conformal deposition process.

A recess etch process can be performed to recess portions of the metallic fill material and the metallic barrier liner layer that are more distal from the bonding interface between the memory die 900 and the logic die 700 than the backside surface of the at least one backside dielectric layer 17. Each remaining portion of the metallic fill material and the metallic barrier liner layer located in a combination of a contact via cavity 85 and a layer-contact via opening 81 constitutes a layer contact via structure (e.g., word line contact via structure) 86. A remaining portion of the metallic fill material and the metallic barrier liner layer located in a source-contact backside opening 5 constitutes a source contact via structure 6.

Each layer contact via structure 86 vertically extends through a respective subset of the electrically conductive layers 46. The respective subset of the electrically conductive layers 46 includes at least the bottommost electrically conductive layer 46 and may optionally include additional electrically conductive layers 46. The total number of the electrically conductive layers within the respective subset of the electrically conductive layers 46 may be less than the total number of the electrically conductive layers 46 within the alternating stack (32, 46) except for the case in which the layer contact via structure 86 directly contacts the topmost electrically conductive layer 46 within the alternating stack (32, 46). Generally, the topmost electrically conductive layer within any subset of the electrically conductive layers 46 includes N consecutive electrically conductive layers 46 including the bottommost electrically conductive layer. Each layer contact via structure 86 comprises a respective metallic barrier liner 86B in direct contact with the segment of the top surface of a respective topmost electrically conductive layer 46 within the respective subset of the electrically conductive layers 46. Further, each layer contact via structure 86 comprises a respective metallic fill material portion 86F that is laterally surrounded by the respective metallic barrier liner 86B. The respective metallic fill material portion 86F comprises a horizontally-extending plate portion that is spaced from the top surface of the respective topmost electrically conductive layer 46 by a horizontally-extending portion of the metallic barrier liner 86B. Each metallic barrier liner 86B may be in direct contact with a segment of a top surface of a respective topmost electrically conductive layer 46 within a respective subset of the electrically conductive layers 46 through which the metallic barrier liner 86B vertically extends. Alternatively, if the metallic barrier liner 86B is omitted, then each metallic fill material portion 86F may be in direct contact with a segment of a top surface of a respective topmost electrically conductive layer 46 within a respective subset of the electrically conductive layers 46 through which the metallic fill material portion 86F vertically extends.

The source contact via structure 6 can be formed on the backside of the source layer 110 concurrently with formation of the layer contact via structure 86. The source contact via structure 6 comprises a metallic fill material portion 6F that is laterally surrounded by the metallic barrier liner 6B. The source contact via structure 6 and the layer contact via structures 86 consist of the at least one conductive material, i.e., a same set of at least one conductive material such as the set of the material of the metallic barrier liners (86B, 6B) and the material of the metallic fill material portions (86F, 6F).

Generally, each layer contact via structure 86 can be formed by replacing a combination of a sacrificial pillar structure 26 and a sacrificial plate structure (71, 73) with portions of at least one conductive material. Each layer contact via structure 86 contacts a segment of a top surface of a respective electrically conductive layer 46 of the electrically conductive layers 46. In one embodiment, each electrically conductive layer 46 may have a respective top surface segment that is contacted by a respective one of the layer contact via structures 86.

While FIG. 32 illustrates one logic die 700 bonded to the top of the memory die 900, in other embodiments, the semiconductor structure may include plural logic die 700 and/or plural memory die 900 that are bonded to each other. For example, one logic die 700 may be bonded over the top of the memory die 900, while another logic die may be bonded under the bottom of the memory die 900, as described in U.S. patent application Ser. No. 17/498,100 filed on Oct. 11, 2021 and incorporated herein by reference in its entirety.

Referring collectively to FIGS. 1-32 and according to various embodiments of the present disclosure, a semiconductor structure is provided, which comprises: an alternating stack (32, 46) of insulating layers 32 and electrically conductive layers 46, wherein the electrically conductive layers 46 have different lateral extents that decrease along an upward vertical direction from a bottommost insulating layer 32B to a topmost insulating layer 32T of the insulating layers 32; a memory opening 49 vertically extending through the alternating stack (32, 46); a memory opening fill structure 58 located in the memory opening 49 and comprising a vertical stack of memory elements and a vertical semiconductor channel 60; and a layer contact via structure 86 vertically extending through a subset of the electrically conductive layers 46 and a subset of the insulating layers 32 that includes a bottommost insulating layer 32B of the insulating layers 32, contacting a top surface of a topmost electrically conductive layer within the subset of the electrically conductive layers 46, and having a topmost surface below a horizontal plane (such as a first horizontal plane HP1) including a topmost surface of the alternating stack (32, 46).

In one embodiment, the semiconductor structure comprises a backside dielectric layer 17 contacting a bottom surface of the bottommost insulating layer 32B, wherein the layer contact via structure 86 vertically extends through the backside dielectric layer 17. In one embodiment, the layer contact via structure 86 comprises: a via portion 86V that vertically extends through the subset of the electrically conductive layers 46 and the subset of the insulating layers 32; and a plug portion 86G that vertically extends through the backside dielectric layer 17, adjoined to a bottom end of the via portion 86V, and having a greater lateral extent than the via portion 86V. In one embodiment, the plug portion 86G comprises a tapered sidewall that vertically extends through the backside dielectric layer 17; and a lateral extent of the plug portion 86G increase with a downward vertical distance from a horizontal plane (such as a second horizontal plane HP2) including a top surface of the backside dielectric layer 17.

In one embodiment, the layer contact via structure 86 comprises: a via portion 86V that vertically extends through the subset of the electrically conductive layers 46 and the subset of the insulating layers 32; and a plate portion 86T that overlies a horizontal plane (such as a third horizontal plane HP3) including the top surface of the topmost electrically conductive layer 46 within the subset of the electrically conductive layers 46 and has a bottom surface that contacts a segment of the top surface of the topmost electrically conductive layer 46.

In one embodiment, the layer contact via structure 86 comprises: a metallic barrier liner 86B in direct contact with the segment of the top surface of the topmost electrically conductive layer 46; and a metallic fill material portion 86F that is laterally surrounded by the metallic barrier liner 86B and comprises a horizontally-extending plate portion that is spaced from the top surface of the topmost electrically conductive layer 46 by a horizontally-extending portion of the metallic barrier liner 86B.

In one embodiment, a stepped dielectric material portion 65 can be provided, which has a horizontal top surface and a stepped bottom surface that contacts the electrically conductive layers 46 and the layer contact via structure 86. In one embodiment, the stepped dielectric material portion 65 is in direct contact with an entirety of a top surface of the plate portion 86T, an entirety of all sidewalls of the plate portion 86T, and segments of top surfaces of the electrically conductive layers 46. In one embodiment, the stepped dielectric material portion 65 is in direct contact with sidewalls of the electrically conductive layers 46 and sidewalls of the insulating layers 32; and each sidewall of the electrically conductive layers 46 that is in direct contact with the stepped dielectric material portion 65 is vertically coincident with a sidewall of a respective underlying insulating layer 32 of the insulating layers 32.

In one embodiment, a dielectric spacer 24A can laterally surround a via portion 86V of the layer contact via structure 86, and can vertically extend through, and can contact each electrically conductive layer 46 and each insulating layer 32 within, the subset of the electrically conductive layers 46 and the subset of the insulating layers 32.

In one embodiment, the layer contact via structure 86 comprises a plate portion 86T that laterally extends horizontally, and has a bottom surface that contacts a segment of the top surface of the topmost electrically conductive layer within the subset of the electrically conductive layers 46 and contacts an annular top surface of the dielectric spacer 24A; and the plate portion 86T has a greater lateral extent than the dielectric spacer 24A.

In one embodiment, the semiconductor structure comprises additional layer contact via structures 86 vertically extending through a respective subset of the electrically conductive layers 46 and a respective subset of the insulating layers 32 that includes the bottommost insulating layer 32B of the insulating layers 32, contacting a top surface of a respective topmost electrically conductive layer within the respective subset of the electrically conductive layers 46, and having a respective topmost surface below the horizontal plane (such as the third horizontal plane HP3) including the topmost surface of the alternating stack (32, 46), wherein a total number of electrically conductive layers 46 within the subsets of the electrically conductive layers 46 for the additional layer contact via structures 86 are different of the subsets of the electrically conductive layers 46.

In one embodiment, the alternating stack (32, 46), the memory opening fill structure 58, and the layer contact via structures 86 are located within a memory die 900; and the semiconductor structure further comprises a logic die 700 that is bonded to the memory die 900 and comprises a peripheral circuit 720 configured to control operation of the memory elements of the memory opening fill structure 58.

In one embodiment, the semiconductor structure comprises: a source layer 110 contacting a sidewall portion of the vertical semiconductor channel 60; and a source contact via structure 6 contacting or electrically connected to the source layer 110 and comprising a same set of metallic materials as the layer contact via structure 86.

In various embodiments, the layer contact via structures 86 are formed in relatively low aspect ratio openings 85 compared to those in prior art structures, which simplifies the layer contact via structure 86 formation and reduces process cost. Furthermore, since the openings 19 and 29 are formed during the same lithography and etching steps, there is a decreased likelihood that the support pillar structures 20 in the support openings 19 overlap with the layer contact via structures 86. Finally, since the plate portion 86T contacts a horizontal surface of the respective electrically conductive layer 46, the likelihood of open circuits is decreased compared to prior art structures in which the layer contact via structures 86 only contact a vertical sidewall of the respective electrically conductive layer 46.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor structure, comprising:
an alternating stack of insulating layers and electrically conductive layers, wherein the electrically conductive layers have different lateral extents that decrease along an upward vertical direction from a bottommost insulating layer to a topmost insulating layer of the insulating layers;
a memory opening vertically extending through the alternating stack;
a memory opening fill structure located in the memory opening and comprising a vertical stack of memory elements and a vertical semiconductor channel; and
a layer contact via structure vertically extending through a subset of the electrically conductive layers and a subset of the insulating layers that includes the bottommost insulating layer, contacting a top surface of a topmost electrically conductive layer within the subset of the electrically conductive layers, and having a topmost surface below a horizontal plane including a topmost surface of the alternating stack.

2. The semiconductor structure of claim 1, further comprising a backside dielectric layer contacting a bottom surface of the bottommost insulating layer, wherein the layer contact via structure vertically extends through the backside dielectric layer.

3. The semiconductor structure of claim 2, wherein the layer contact via structure comprises:
a via portion that vertically extends through the subset of the electrically conductive layers and the subset of the insulating layers; and
a plug portion that vertically extends through the backside dielectric layer, adjoined to a bottom end of the via portion, and having a greater lateral extent than the via portion.

4. The semiconductor structure of claim 3, wherein:
the plug portion comprises a tapered sidewall that vertically extends through the backside dielectric layer; and
a lateral extent of the plug portion increase with a downward vertical distance from a horizontal plane including a top surface of the backside dielectric layer.

5. The semiconductor structure of claim 1, wherein the layer contact via structure comprises:
a via portion that vertically extends through the subset of the electrically conductive layers and the subset of the insulating layers; and
a plate portion that overlies a horizontal plane including the top surface of the topmost electrically conductive layer within the subset of the electrically conductive layers and has a bottom surface that contacts a segment of the top surface of the topmost electrically conductive layer.

6. The semiconductor structure of claim 5, wherein the layer contact via structure further comprises:
a metallic barrier liner in direct contact with the segment of the top surface of the topmost electrically conductive layer; and
a metallic fill material portion that is laterally surrounded by the metallic barrier liner and comprises a horizontally-extending plate portion that is spaced from the top surface of the topmost electrically conductive layer by a horizontally-extending portion of the metallic barrier liner.

7. The semiconductor structure of claim 5, further comprising a stepped dielectric material portion having a horizontal top surface and a stepped bottom surface that contacts the electrically conductive layers and the layer contact via structure.

8. The semiconductor structure of claim 7, wherein the stepped dielectric material portion is in direct contact with an entirety of a top surface of the plate portion, an entirety of all sidewalls of the plate portion, and segments of top surfaces of the electrically conductive layers.

9. The semiconductor structure of claim 7, wherein:
the stepped dielectric material portion is in direct contact with sidewalls of the electrically conductive layers and sidewalls of the insulating layers; and
each sidewall of the electrically conductive layers that is in direct contact with the stepped dielectric material portion is vertically coincident with a sidewall of a respective underlying insulating layer of the insulating layers.

10. The semiconductor structure of claim 1, further comprising a dielectric spacer laterally surrounding a via portion of the layer contact via structure and vertically extending through, and contacting each electrically conductive layer and each insulating layer within the subset of the electrically conductive layers and the subset of the insulating layers.

11. The semiconductor structure of claim 10, wherein:
the layer contact via structure comprises a plate portion that laterally extends horizontally, and has a bottom surface that contacts a segment of the top surface of the topmost electrically conductive layer within the subset of the electrically conductive layers and contacts an annular top surface of the dielectric spacer; and
the plate portion has a greater lateral extent than the dielectric spacer.

12. The semiconductor structure of claim 1, further comprising additional layer contact via structures vertically extending through a respective subset of the electrically conductive layers and a respective subset of the insulating layers that includes the bottommost insulating layer of the insulating layers, contacting a top surface of a respective topmost electrically conductive layer within the respective subset of the electrically conductive layers, and having a respective topmost surface below the horizontal plane including the topmost surface of the alternating stack, wherein a total number of electrically conductive layers within the subsets of the electrically conductive layers for the additional layer contact via structures are different among the subsets of the electrically conductive layers.

13. The semiconductor structure of claim 1, wherein:
the alternating stack, the memory opening fill structure, and the layer contact via structures are located within a memory die; and
the semiconductor structure further comprises a logic die that is bonded to the memory die and comprises a peripheral circuit configured to control operation of the memory elements of the memory opening fill structure.

14. The semiconductor structure of claim 1, further comprising:
a source layer contacting sidewall portion of the vertical semiconductor channel; and
a source contact via structure contacting or electrically connected to the source layer and comprising a same set of metallic materials as the layer contact via structure.

15. A method of forming a semiconductor structure, comprising:
forming an alternating stack of insulating layers and sacrificial material layers over a carrier substrate;
forming an in-process assembly including a dielectric spacer and a sacrificial pillar structure through the alternating stack;
forming a memory opening through the alternating stack;
forming a memory opening fill structure in the memory opening, wherein the memory opening fill structure comprises a vertical stack of memory elements and a vertical semiconductor channel;
forming stepped surfaces by patterning the alternating stack, wherein the alternating stack has lateral extents that decrease stepwise as a function of a vertical distance from the carrier substrate, and the in-process assembly is recessed during patterning of the alternating stack;
forming a sacrificial plate structure over a top surface of the in-process assembly;
replacing the sacrificial material layers with electrically conductive layers;
removing the carrier substrate; and
forming a layer contact via structure by replacing the sacrificial pillar structure and the sacrificial plate structure with portions of at least one conductive material, wherein the layer contact via structure contacts a segment of a top surface of an electrically conductive layer of the electrically conductive layers.

16. The method of claim 15, further comprising:
forming a backside dielectric layer on a bottom side of the alternating stack after removal of the carrier substrate; and
forming a backside opening through the backside dielectric layer such that a bottom surface of the in-process assembly is exposed, wherein the in-process assembly is removed after formation of the backside opening, and the layer contact via structure fills a volume of the backside opening.

17. The method of claim 15, wherein:
the sacrificial plate structure comprises a layer stack including a sacrificial etch stop liner and a sacrificial material plate portion; and
the method further comprises forming lateral recesses by performing an etch process that etches the sacrificial material layers selective to the insulating layers and the sacrificial etch stop liner, and forming the electrically conductive layers by depositing at least one electrically conductive material in the lateral recesses.

18. The method of claim 17, further comprising:
removing the sacrificial pillar structure selective to the sacrificial etch stop liner;
removing the sacrificial etch stop liner selective to the electrically conductive layers; and
removing the sacrificial material plate portion selective to the insulating layers, wherein the layer contact via structure is formed in volumes from which the sacrificial pillar structure, the sacrificial etch stop liner, and the sacrificial material plate portion are removed.

19. The method of claim 15, further comprising forming a stepped dielectric material portion over the stepped surfaces and the in-process assembly after formation of the sacrificial plate structure.

20. The method of claim 15, further comprising:
forming a source layer directly on a physically exposed sidewall surface of the vertical semiconductor channel; and
forming a source contact via structure on a backside of the source layer concurrently with formation of the layer contact via structure, wherein the source contact via structure and the layer contact via structure comprise the at least one conductive material.
